(19) United States
(12) Patent Application Publication
(10) Pub. No.: US 2025/0275460 A1
(43) Pub. Date: Aug. 28, 2025

(54) PEROVSKITE SOLAR CELL WITH INTERFACE LAYER

(71) Applicants: IMPERIAL COLLEGE INNOVATIONS LIMITED, London (GB); CITY UNIVERSITY OF HONG KONG, Hong Kong (CN)

(72) Inventors: Nicholas Long, London (GB); Stephanie Sheppard, London (GB); Zonglong Zhu, Hong Kong (CN); Zhen Li, Hong Kong (CN)

(21) Appl. No.: 18/858,396

(22) PCT Filed: Apr. 20, 2023
(86) PCT No.: PCT/EP2023/060281

§ 371 Date: Oct. 21, 2024

(30) Foreign Application Priority Data
Apr. 20, 2022 (GB) 2205772.3

(51) Int. Cl. H10K 85/30; H10K 30/40; H10K 30/50; H10K 30/80; H10K 30/85; H10K 39/12; H10K 85/20; H10K 85/50

(52) U.S. Cl. CPC H10K 85/331; H10K 30/50; H10K 30/865; H10K 30/40; H10K 30/85; H10K 39/12; H10K 85/211; H10K 85/50

(57) ABSTRACT

A photovoltaic cell comprising a perovskite layer (110), an electron transporting layer (106) and an interface layer (108) disposed between the electron transporting layer and the perovskite layer. The interface layer comprises a metallocene substituted with a substituent having an O, S, N or P group, for example ferrocene substituted with a thienyl-carboxylate group.

### FIELD

This relates to materials for interface layers for metal halide perovskite solar cells and a photovoltaic cell comprising an interface layer.

### BACKGROUND

Metal halide perovskites are cheap, and simple to manufacture via a range of different fabrication process and techniques. Metal halide perovskites are commonly used as light absorbing layers in thin film solar cells, leading to the provision of low-cost, lightweight solar cells. Such metal halide perovskite solar cells (metal halide PVSCs) have emerged as a ground-breaking photovoltaic technology, with power conversion efficiencies (PCE) of 25.5% being realized for single-junction PVSCs. PVSCs have now surpassed the efficiency of commercialized thin-film solar cells (such as cadmium telluride, CdTe, or copper indium gallium selenide, CIGS) and approach the efficiency of state-of-the-art crystalline-silicon solar cells.

WO2017160955 discloses perovskite-based photoactive devices, such as solar cells, which includes an insulating tunnelling layer inserted between the perovskite photoactive material and the electron collection layer.

CN113193124 discloses a triethylamine hydrochloride modified perovskite solar cell comprising transparent conductive glass, a tin dioxide electron transport layer, a triethylamine hydrochloride layer, a perovskite absorption layer, a hole transport layer and a metal electrode which are arranged in sequence.

WO2015092397 discloses photovoltaic and optoelectronic devices comprising passivated metal halide perovskites comprising (a) a metal halide perovskite; and (b) a passivating agent which is an organic compound; wherein molecules of the passivating agent are chemically bonded to anions or cations in the metal halide perovskite.

WO2018137048 discloses perovskite based optoelectronic devices using an electron transport layer on which the perovskite layer is formed which is passivated using a ligand selected to reduce electron-hole recombination at the interface between the electron transport layer and the perovskite layer.

CN110993803 discloses formation of a passivation layer on the perovskite grain boundary and a perovskite/hole transport layer interface of a perovskite solar cell.

CN109360889 discloses solar cell which is, sequentially from bottom to top, provided with a transparent conductive substrate, a hole transport layer, a perovskite thin film, an interface passivation layer, an electron transport layer and a cathode.

Organic interface materials (OIMs) are known. These organic materials provide flexibility, uniformity and multi-functionality as interlayers in PVSCs. However, OIMs typically show poor conductivity and carrier mobility, forming interface barriers and impeding charge carrier transport. Moreover, they exhibit chemical or photochemical instability, which can affect the long-term stability of the photovoltaic devices.

Inorganic interface materials (IIMs) are also known for PVSCs. Such IIMs typically have intrinsic thermal and chemical stability, and exhibit high carrier conductivity and good stability as interlayers in PVSCs. However, they are structurally rigid (not as flexible as organic materials), which prevents the close contact and interaction with perovskite surface. Moreover, some inorganic interface materials (such as 2D transition metal chalcogenides) show inhomogeneous coverage on perovskite surfaces, which can result in more non-radiative recombination.

Poor lifetimes and instabilities still affect the commercial prospects of PVSCs. It is desirable to address these drawbacks with PVSCs, and provide a stable and efficient photovoltaic cell.

### SUMMARY

In a first aspect, the invention provides a photovoltaic cell comprising:
a first electrode;
a second electrode;
a perovskite layer and an electron transport layer disposed between the first and second electrodes; and
an interface layer disposed between the perovskite layer and the electron transport layer. The interface layer is in direct contact with the perovskite layer. The interface layer comprises or consists of an interfacial compound comprising a metallocene substituted with at least one substituent R¹ comprising at least one of an O, S, N or P atom.

Optionally, the interfacial compound is a compound of formula (I):

[Metallocene]p (I)
wherein:
Metallocene is a metallocene group comprising a metal bound to two aromatic or heteroaromatic groups Ar¹;
p is at least 1; and
at least one Metallocene is substituted with at least one substituent R¹.

Optionally, the compound of formula (I) has formula (Ia):

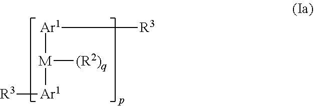

wherein:
M is a metal ion;
Ar¹ in each occurrence is a monocyclic or polycyclic aromatic or heteroaromatic group;
M and the two Ar¹ groups form the Metallocene;
at least one Ar¹ is substituted with at least one R¹;
R² is a group for satisfying the valency of M;
q is 0 or a positive integer; and
R³ in each occurrence is independently H or a substituent.

Optionally, the metallocene is ferrocene.

Optionally, R¹ is a group of formula (II):

-A-B (II)
wherein A is a divalent group comprising O, S, N or P; and B is H, C₁₋₁₂ alkyl, optionally substituted aryl or optionally substituted heteroaryl.

Optionally, A is selected from groups of formulae:

—(R⁵)_{f}—Z—(R⁵)g- (III)

—(R⁶O)ⱼ— (IV)
wherein:
R⁵ in each occurrence is independently a hydrocarbon group;
f and g are each independently 0 or 1;
R⁶ is a C1-4 alkylene group, preferably ethylene; and
Z is O, S, COO, C(═S)O, C(═O)S, CONR⁴, CSNR⁴, OC(═O)O, OC(═O)NR⁴, OC(═O)PR⁴, NR⁴, PR⁴, —OP(═O)(OR⁴)—O—, —NR⁴—P(═O)(NR⁴₂)—NR⁴—, wherein R⁴ is H, optionally substituted C₁₋₁₂ alkyl or optionally substituted phenyl.

In some preferred embodiments, the bond between the metallocene and R¹ is a carbon-oxygen bond in which a C atom of the metallocene is bound to an O atom of R¹.

Optionally, A is —O—C(═O)—.

Optionally, B is selected from optionally substituted phenyl and an optionally substituted 5 membered heteroaryl comprising one or more ring atoms selected from O, S and N.

Optionally, B is optionally substituted thiophene.

Optionally, the perovskite layer comprises a perovskite of formula CatPbX₃ or CatSnX₃ wherein Cat is a metal cation, an organic cation or a combination thereof and X is selected from at least one of I, Br and Cl.

Optionally, the electron transport layer comprises a fullerene.

In a second aspect the invention provides a photovoltaic module comprising a plurality of the photovoltaic cells according to any one of the preceding claims, the photovoltaic cells connected in series.

In a third aspect the invention provides a compound of formula (I):

[Metallocene]p (I)
wherein:
Metallocene is a metallocene group comprising a metal bound to two aromatic or heteroaromatic groups Ar¹;
p is at least 1; and
at least one Metallocene is substituted with at least one substituent R¹ wherein R¹ is a group of formula (II):

-A-B (II)
wherein A is a divalent group comprising O, S, N or P; and B is optionally substituted aryl or optionally substituted heteroaryl.

Optionally according to the third aspect, Ar¹ is optionally substituted cyclopentadienyl.

Optionally according to the third aspect, Metallocene is ferrocene.

Optionally according to the third aspect, A is selected from groups of formulae:

—(R⁵)_{f}—Z—(R⁵)g- (III)

—(R⁶O)ⱼ— (IV)
wherein:
R⁵ in each occurrence is independently a hydrocarbon group;
f and g are each independently 0 or 1;
R⁶ is a C1-4 alkylene group, preferably ethylene;
j is 1-10; and
Z is O, S, COO, C(═S)O, C(═O)S, CONR⁴, CSNR⁴, OC(═O)O, OC(═O)NR⁴, OC(═O)PR⁴,
NR⁴, PR⁴, —OP(═O)(OR⁴)—O—, —NR⁴—P(═O)(NR⁴₂)—NR⁴—, wherein R⁴ is H, optionally substituted C₁₋₁₂ alkyl or optionally substituted phenyl.

Optionally according to the third aspect, A is —O—C(═O)—.

Optionally according to the third aspect, B is selected from optionally substituted phenyl and an optionally substituted 5 membered heteroaryl comprising one or more ring atoms selected from O, S and N.

Optionally according to the third aspect, B is optionally substituted thiophene.

### LIST OF FIGURES

FIG. 1A provides a schematic illustration of a conventional perovskite solar cell comprising an interface layer, and FIG. 1B provides a schematic illustration of an inverted perovskite solar cell comprising the interface layer;

FIG. 2 illustrates substituted metallocenes suitable for use in an interfacial layer;

FIG. 3: FIG. 3A provides a schematic illustration of an example inverted perovskite solar cell of FIG. 1B with a FcTc₂ interface functionalization material, FIG. 3B shows a cross-section SEM image of a fabricated inverted PVSC having the structure of FIG. 3A, and FIG. 3C shows TOF-SIMS characterization of the perovskite solar cell of FIG. 3B;

FIG. 4: FIG. 4A shows the X-ray photo-electron spectroscopy (XPS) characterization of the binding energy of Pb, FIG. 4B shows the XPS characterization of N, and FIG. 4C shows the XPS characterization of I;

FIG. 5 shows surface potential images obtained by scanning Kelvin probe microscopy of perovskite films, where the bottom graph is the statistical potential distribution of the film surfaces for a control device (FIG. 5A) and FcTc₂-treated perovskite films comprising an interface layer (FIG. 5B);

FIG. 6 shows the time-resolved photoluminescence (TRPL) spectra of a device comprising perovskite/FcTc2/C60 (having interface layer) and device comprising perovskite/C60 (control);

FIG. 7 shows the steady-state PL spectra of perovskite films with different concentrations of FcTc₂ (0, 0.5, 1.0 and 2.0 mg mL⁻¹), excited via a laser with the wavelength of 485 nm;

FIG. 8 shows PFIR microscopy at an IR frequency of 1480 cm⁻¹ (which is resonant with the C—N stretching absorption of MA⁺ ion): FIG. 8A shows FcTc₂-modified perovskite films before illumination, FIG. 8B shows FcTc₂-modified perovskite films after illumination at 85° C. for 1000 hours, FIG. 8C shows control perovskite films before illumination, and FIG. 8D shows control perovskite films after illumination at 85° C. for 1000 hours;

FIG. 9 shows J-V curves of the best performing devices with and without FcTc₂ interface layer;

FIG. 10 shows EQE spectra and integrated current densities of the best performing devices with and without FcTc₂;

FIG. 11 shows a histogram of the measured PCE values among 30 devices with and without FcTc₂;

FIG. 12 shows normalized PCE values of unencapsulated PVSCs with or without FcTc₂ measured at the maximum power point (MPP) under continuous one-sun illumination in N₂ atmosphere and at room temperature;

FIG. 13 shows the results of stability tests based on unencapsulated devices with and without FcTc₂ under continuous heating at 85° C. in N₂ atmosphere (FIG. 13A) and stored in ambient air (RH 40-50%, 25° C.) in the dark (FIG. 13B);

FIG. 14 shows normalized PCE data for encapsulated devices stored in 85% RH and 85° C. in the dark (FIG. 14A) and encapsulated devices stored in −40° C. (15 min dwell) to 85° C. (15 min dwell), ramp rate of 100° C./hour (FIG. 14B);

FIG. 15A shows J-V curves of the best performing MAPbI₃ based PVSCs with and without FcTc₂, and FIG. 15B shows a histogram of measured PCE values among 20 devices of MAPbI₃ based PVSCs with and without FcTc₂;

FIG. 16A shows J-V curves of the best performing CS_{0.05}(FA_{0.85}MA_{0.15})_{0.95}Pb(I_{0.85}Br_{0.15})₃ based PVSCs with and without FcTc₂, and FIG. 16B shows a histogram of measured PCE values among 20 devices of CS_{0.05}(FA_{0.85}MA_{0.15})_{0.95} Pb(I_{0.85}Br_{0.15}), based PVSCs with and without FcTc₂;

FIG. 17A shows J-V curves of the best performing FAPbI₃ based PVSCs with and without FcTc2, and FIG. 17B shows a histogram of measured PCE values among 20 devices of FAPbI₃ based PVSCs with and without FcTc₂;

FIGS. 18A and 18B show SCLC curves of perovskite films with (FIG. 18A) and without (FIG. 18B) FcTc₂ based on an electron-only device structure, and FIG. 18C shows TRPL spectra of perovskite/FcTc₂/C60 and perovskite/C60;

FIG. 19 shows J-V curves of the best performing devices of PVSCs based on a control device (FIG. 19A) and a device with a FcPh₂ interface layer (FIG. 19B);

FIG. 20 shows J-V curves of the best performing devices of PVSCs based on a control device (FIG. 20A) and a device with a DPC interface layer (FIG. 20B);

FIG. 21 shows J-V curves of the best performing devices of PVSCs based on a control device (FIG. 20A) and a device with a BA interface layer (FIG. 20B);

FIG. 22 shows the UV-vis spectrum of the FcTc₂ in solution (FIG. 22A) and thin film (FIG. 22B) form;

FIG. 23 shows density functional theory (DFT) simulations of the interaction between FAPbI₃ and FcTc₂ molecules; and

FIG. 24 shows electrostatic potential (ESP) analysis of FcTc₂.

FIG. 25 shows surface molecule interaction of a, Functionalized Fc-based compound structures. b, Electrostatic potential of Fc-based compounds via DFT simulation. c, d, XPS spectra of elemental Pb and I; e, XPS spectra of Fe within the different Fc compounds on the perovskite surface. f, g, EFM characterization of phase images of perovskite films with and without Fc compounds, where the bias voltage is supplied to the tip (−3 to 3 V, 1.5 V step) to enable the extraction of the Coulombic forces. h, Phase plots in relation to applied bias.

FIG. 26 shows potential evolution and carrier dynamics for a-d, KPFM of surface contact potential difference (CPD) of perovskite films treated with different Fc compounds, e-h, Statistics of surface work function of perovskite films, i, TRPL spectra of perovskite/ETL films with different Fc compounds. j, Integral fit value of PL mapping intensity for perovskite/ETL films with different Fc compounds, k, Statistics of trap-filling voltage V_{TFL} and EQE of EL values for perovskite devices with different Fc compounds.

FIG. 27 shows PV performance. a, Schematic of device structure. b, Cross-section SEM image of the PSC. c, J-V curves of the best-performing PSCs treated with different Fc compounds. d, The highest PCEs of the PSCs treated with different Fc compounds. e, J-V curves of forward and reverse scan of the device with Fc₂Tc₂. f, EQE and integrated current density. g, Stabilized power output of the Fc₂Tc₂-treated PSC. h, The PV parameter statistics for the control and Fc₂Tc₂-treated PSCs. Mask area is 0.0414 cm².

FIG. 28 shows PV performance and uniformity of large-area device for a, J-V curves of the best-performing pristine and Fc₂Tc₂-treated PSCs with a masked area of 1.008 cm². b, Stabilized power output of the Fc₂Tc₂-treated large-area PSC. Inset is the top-view device image. c, Statistical distribution of V_{OC} and FF for 20 pristine and target devices. d, J-V curves for a representative Fc₂Tc₂-treated PSC measured from five different spots with an aperture area of 0.0414 cm² selected from the total active area. e, Statistics of normalized PV parameters and CV values of small-area selected from large-area PSCs. The data was recorded from five separate points on four devices and normalized to the highest value of each parameter. f, Statistics of normalized PL on perovskite/ETL with and without Fc₂Tc₂ treatment. CV is coefficient of variation.

FIG. 29A-E shows J-V curves of functionalized ferrocene compounds for perovskite solar cells.

FIG. 30 shows efficiency evolution of large-area and small-area PSCs with regular and inverted structures, and efficiency gap between large-area and small-area PSCs.

FIG. 31 shows XPS spectra of elemental Pb in perovskite films with different Fc compounds.

FIG. 32 shows XPS spectra of elemental I in perovskite films with different Fc compounds.

FIG. 33 shows UV-vis absorption spectra of perovskite films with different Fc compounds.

FIG. 34 shows AFM images of perovskite films with different Fc compounds.

FIG. 35 shows a, c EFM characterization of phase images of perovskite films with FcTc₂ and Fc₃ Tc₂ compounds, where the bias voltage is supplied to the tip (−3 to 3 V, 1.5 V step) to enable the extraction of the Coulombic forces. b, d Phase plots of perovskite films with FcTc₂ and Fc₃Tc₂ compounds in relation to applied bias.

FIG. 36 shows statistics of phase angle of pristine perovskite films under different applied bias voltages.

FIG. 37 shows statistics of phase angle of Fc-modified perovskite films under different applied bias voltages.

FIG. 38 shows TOF-SIMS plots of Fc₂Tc₂-modified perovskite solar cells.

FIG. 39 shows steady-state PL spectra of perovskite films with different Fc compounds treatment.

FIG. 40 shows PL mapping of the perovskite films with a) control, b) FcTc₂, C) Fc₂Tc₂ and d) Fc₃ Tc₂ modification.

FIG. 41 shows thickness measurement of perovskite films based on Dektak XTL.

FIG. 42 shows SCLC characterization of defect density of the pristine and modified perovskite films with different Fc-based compounds based on an electron-only device (FTO/TiO₂/perovskite/Fc/C60/BCP/Ag).

FIG. 43 shows light-independent open-circuit voltage for pristine and Fc-modified PSCs.

FIG. 44 shows EL spectra of the perovskite devices with a) control, b) FcTc₂, c) Fc₂Tc₂ and d) Fc₃ Tc₂ modification under different voltage bias operating as LEDs.

FIG. 45 shows EQE of EL plots for the control, FcTc₂-, Fc₂Tc₂- and Fc₃Tc₂-treated PSCs.

FIG. 46 shows J-V curves of forward and reverse scans of best-performing pristine PSC.

FIG. 47 shows J-V curves of the best-performing PSCs modified with different concentrations of Fc₂Tc₂.

FIG. 48 shows PCE statistics of the PSCs modified with different Fc compounds and varied concentrations.

FIG. 49 shows sensitive EQE of pristine and Fc₂Tc₂-treated PSCs.

FIG. 50 shows statistics of energy loss for control and Fc₂Tc₂-treated PSCs.

FIG. 51 shows long-term operational stability measurements of encapsulated devices at room temperature in N₂ atmosphere, under AM 1.5 G simulated sunlight illumination. One point out of every 70 points is selected as the representative point shown in each curve.

FIG. 52 shows 5 points PL spectra of a) pristine perovskite/ETL films and b) Fc₂Tc₂-treated perovskite/ETL films.

FIG. 53 shows KPFM image and potential distribution of control films at three different sites.

FIG. 54 shows a KPFM image and potential distribution of Fc₂Tc₂-treated films at three different sites.

### DETAILED DESCRIPTION

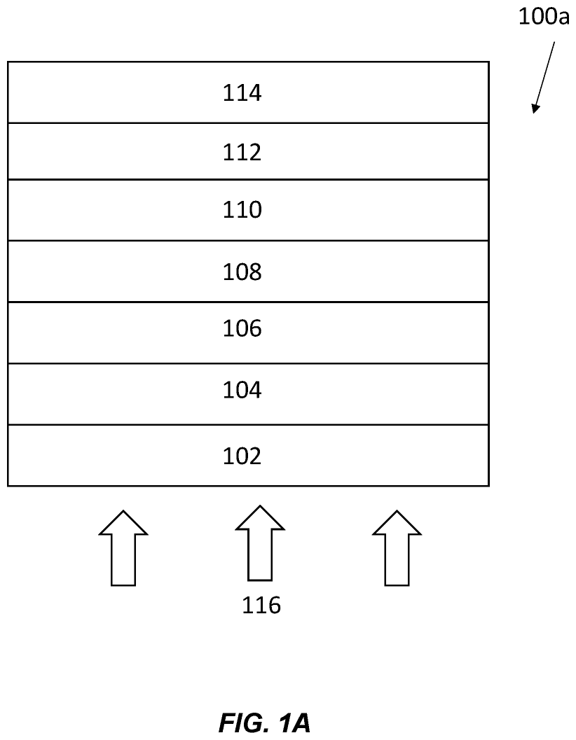

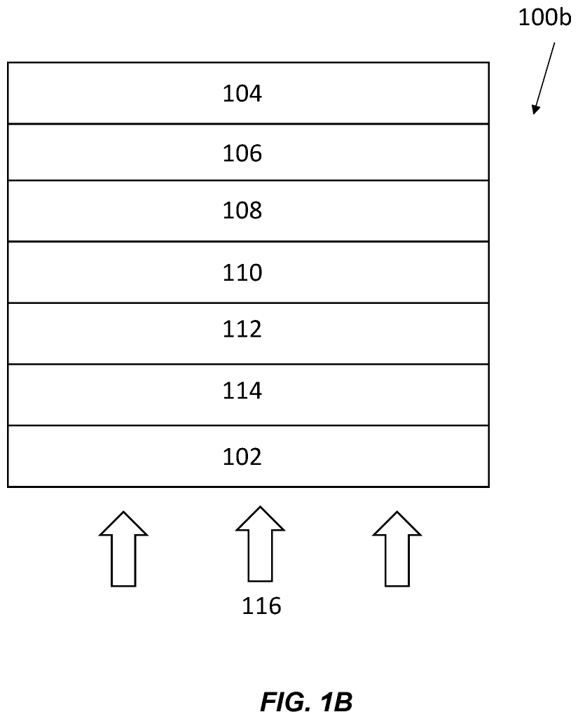

With reference to FIG. 1A, a ‘conventional’ perovskite photovoltaic cell (also termed herein a perovskite solar cell) 100a comprising an n-p or n-i-p junction is described (where electrons are collected at a transparent electrode). With reference to FIG. 1B, an ‘inverted’ perovskite photovoltaic cell (also termed herein a perovskite solar cell) 100b comprising a p-n or p-i-n junction is described (where holes are collected at a transparent electrode). In the following discussion of FIG. 1 (FIG. 1A and FIG. 1B), like reference numerals refer to like features.

Among perovskite solar cells (PVSCs), inverted (p-n/p-i-n structure) devices have typically exhibited more stable behaviour than conventional (n-p/n-i-p) PVSCs, due in part to their non-doped hole transporting materials and highly crystalline perovskite films. The following description is with primary reference to inverted PVSCs, but the beneficial effects of an interface layer as described herein apply equally to a conventional (n-i-p) PVSC structure.

A transparent substrate 102 is provided. This forms the base or support for the solar cell structure 100. The photovoltaic cell (solar cell 100) can be implemented as a tandem solar cell. For example, the solar cell 100 can implemented as a tandem perovskite-on-silicon solar cell. The perovskite layer, electron transport layer and interface layer can in this arrangement be provided as part of a perovskite cell, which perovskite cell is formed on, or built on top of, a silicon cell to form the tandem photovoltaic cell (solar cell 100). Visible light 116 (such as incident sunlight) enters the solar cell 100 (e.g. solar cell 100a or 100b) through the transparent substrate 102. Substrate 102 may be formed of glass, or any other suitable transparent material.

Solar cell 100 (e.g. solar cell 100a or 100b) comprises a perovskite layer 110. In use, the perovskite layer 110 absorbs light incident on the solar cell 100. The term ‘light-absorbing’ in relation to the perovskite(s) (and by extension the layer 110 comprising said one or more perovskites) refers to its role in absorbing light, e.g. visible light 116, so as to act as a light absorbing material which allows to convert the light 116 into electrical energy. A perovskite type compound exhibits strong absorption with respect to visible light 116 incident on the solar cell 100, and the bandgap of a perovskite semiconductor can be tuned to a desired band gap energy E_{g}, improving the efficiency of such solar cells.

As in the exemplar solar cell depicted in FIG. 1, solar radiation or visible light 116 passes through the substrate layer 102 into the active layer 110, whereupon at least a portion of the solar radiation 116 is absorbed by exciting an electron across a semiconductor band gap so as to enable electrical generation. In particular, the electron is excited from a valence band of the semiconductor, across the bandgap, to a conduction band. The excited electron sits in the conduction band, and a corresponding hole (a vacancy or absence of an electron, rather than a physical particle in and of itself) remains in the valence band of the semiconductor.

An asymmetry within the functional layer 110 acts to separate the excited electron away from the hole, moving the charge carriers (holes and electrons) away from the point of electron promotion for collection and current generation. In the examples described herein, this asymmetry is provided by a junction within the perovskite layer 110 (such as an n-p or n-i-p junction for solar cell 100a in FIG. 1A, or a p-n or p-i-n junction for solar cell 100b in FIG. 1B). It will therefore be understood that the perovskite layer can include any suitable semiconductor junction. However, the asymmetry within the perovskite layer may be provided in any other suitable manner.

In some examples, the perovskite layer 110 can include one or more heterojunctions. Heterojunctions can be formed within the perovskite layer 110 by way of two different, undoped, perovskite materials. Thus, the perovskites referred to herein may both be undoped semiconductors. Alternatively, the perovskite(s) may be doped with p-type or n-type dopants to form a junction. In other words, they may be doped (throughout and/or at the surface) with at least one dopant material of greater valency than the bulk material (to provide n-type doping) and/or may be doped with at least one dopant material of lower valency than the bulk material (to give p-type doping). N-type doping will tend to increase the n-type character of the semiconductor material, while p-type doping will tend to reduce the degree of the natural n-type state (e.g. due to defects). Such doping may be made with any suitable material including F, Sb, N, Ge, Si, C, In, InO and/or Al. Suitable dopants and doping levels will be evident to those of skill in the art.

In some examples, light-absorbing perovskite layer 110 comprises one or more metal halide perovskites. In some examples, the light-absorbing layer may comprise two different metal halide perovskites configured to form a semiconductor heterojunction within layer 110. Any perovskite(s) capable of performing the desired light-absorbing and charge separation functions may be used in light-absorbing layer 110.

With further reference to solar cell 100, an electron transport layer, ETL, 106 is provided. The ETL (or n-type charge extraction layer) comprises an electron transport material. Any electron transport material known to the skilled person may be used. The ETL may comprise or consist of an organic electron transport material, an inorganic electron transport material or mixtures thereof. Example electron transport materials include organic materials such as fullerenes, metal oxides such as TiO₂, ZnO, SnO₂, SiO₂, or ZrO₂.

Fullerenes are preferred. Fullerenes may be selected from any known fullerene including C₆₀ fullerene and C₇₀ fullerene, each of which is optionally substituted with one or more substituents. Exemplary substituents include C₁₋₁₂ alkyl wherein one or more non-adjacent C atoms of the C₁₋₁₂ alkyl may be replaced with O, S, CO or COO and optionally substituted phenyl, and wherein two substituents may be linked to form a monocyclic or polycyclic ring. Exemplary fullerenes include C₆₀, PCBM and ICBA.

Electron transport materials may encourage a flow of electrons from the n-type perovskite, away from the junction within layer 110, while blocking the movement of holes. In this way, electrons accumulate at a first electrical conductor 104. In use, the first electrical conductor 104 is negatively charged due to the accumulation of electrons. When the solar cell is connected to an external load, the electrons leave the solar cell 100 via the first electrical conductor 104.

A hole transport layer, HTL, 112 comprising or consisting of one or more hole transport materials can also be provided within solar cell 100. In the inverted PVSC of FIG. 1B, the HTL is located proximate to the transparent substrate (holes are collected at the electrode proximate the substrate, converse to the conventional PVSC of FIG. 1A). Any hole-transport material known to the skilled person may be used.

Example hole transport materials include organic hole-transport materials, inorganic hole-transport materials or combinations thereof. Organic hole-transport materials may be polymeric or non-polymeric. Exemplary polymeric hole-transport materials include polythiophenes, for example poly(3-hexylthiophene) (P3HT); poly(arylamines) for example PTTA; and doped PEDOT, for example PEDOT: PSS. Exemplary non-polymeric organic hole-transport materials are compounds containing one or more arylamine groups, for example spiro-OMeTAD. Exemplary inorganic hole-transport materials include copper-based materials (e.g. CuOₓ, CuSCN, CuI, etc.), nickel-based materials (e.g. NiOₓ), two-dimensional layered materials such as chalcogens (e.g. MoS₂, WS₂, etc.). Hole transport materials encourage a flow of holes from the p-type perovskite, away from the junction within layer 110, while blocking the movement of electrons. In this way, holes accumulate at a second electrical conductor 114. In use, the second electrical conductor 114 is positively charged due to the accumulation of holes.

In a conventional PVSC, the first conductor 104 may be any transparent conducting material. In some examples, the first conductor 104 is a transparent conducting film (TCF). In some examples, the TCF is a transparent conducting oxide (TCO) layer. In some examples, the TCO layer comprises indium-tin oxide (ITO), fluorine-doped tin oxide (FTO) or doped zinc oxide. The second conductor 114 may be formed of any suitable conducting material, such as Ag, Au, Cu, etc. In an inverted PVSC, the second conductor 114 may be any transparent conducting material (since in an inverted structure it is this contact which is disposed on the transparent substrate 102), such as a transparent conducting film, or more particularly a TCO. The first conductor 104 may then be formed of any suitable conducting material, such as Ag, Au, Cu, Al, etc. The first and second conductors or contacts are for connection to an external load.

In previous PVSCs, the functional or active perovskite layer 110 has been sandwiched between the HTL 112 and ETL 106. In other words, the charge transporting layers are deposited on the top and the bottom sides of the perovskite active layer, respectively. The charge carriers are extracted at the HTL/perovskite and perovskite/ETL interfaces and collected through the respective conductors/contacts. During this process, the carrier charges may be subject to recombination, for example due to any interfacial defects and associated specific charge distributions.

Interface recombination arises from charge dynamics at the interface (including charge extraction, charge transfer, and charge recombination). The imperfect interfacial structural and electronic mismatches usually act as energy barriers for charge transport and charge recombination. Furthermore, defects at the surface and interface of polycrystalline perovskite films are mostly either positively charged or negatively charged. Trap states at the perovskite surface and interfaces can lead to charge accumulation and recombination losses in the device.

It has been found that the performance of a perovskite solar cell described herein can be improved when an interface layer 108 comprising an interfacial compound as described herein is provided between the electron transport layer 106 and the perovskite layer 110. Such a layer can suppress defects in the perovskite surface and minimize interfacial non-radiative combination losses. In this way, the interface layer 108 improves the extraction of electrons at the perovskite interface, increasing the efficiency of the solar cell, and improves the stability of the solar cell 100.

The interface layer 108 interfaces directly with the perovskite layer 110. In other words, the interface layer 108 and the perovskite layer are in direct contact. The interface layer 108 can be deposited directly on the active perovskite layer 110, as described below, or may be otherwise formed. The interface layer 108 is described below in more detail.

One or more additional layers (not shown) may be provided within the solar cell structure 100. For example, one or more optional hole blocking layers may be provided between the ETL 106 and the contact 104 and/or between the interface layer 108 and the ETL 106. Similarly, one more optional electron blocking layers may be provided between the HTL 112 and the contact 114 and/or between the perovskite layer 110 and the HTL 112. Any other layers may be provided within solar cell 100, as appropriate.

A plurality of photovoltaic cells 100a, 100b can be connected together in series and encapsulated to form a photovoltaic module (not shown). The photovoltaic modules can be used singly, or a plurality can be connected in series and/or parallel into a photovoltaic array, according to the power demanded by a specific load or application.

### Interface Layer

The interface layer comprises or consists of a metallocene substituted with at least one substituent containing an O, S, N or P atom having a lone pair of electrons.

The present inventors have surprisingly found that the presence of such an interface layer can enhance the stability and performance of perovskite solar cells. Moreover, the present inventors have found these benefits may be achievable over a large area cell for example up to 30 cm×30 cm, for instance up to 15 cm×15 cm. Optionally, the cell area is at least 1×1 cm.

Without wishing to be bound by any theory, it is believed that the flexibility of metallocenes around the metal-aromatic bond may ameliorate stresses between the electron transport layer and the perovskite layer.

Further, without wishing to be bound by any theory, it is believed that the lone electron pairs of the O, S, N or P group are capable of binding to uncoordinated metal defects, e.g. Pb defects, at the perovskite surface.

The metallocene preferably is a compound of formula (I):

[Metallocene]p (I)
wherein:
Metallocene is a metallocene group comprising a metal bound to two aromatic or heteroaromatic groups Ar¹;
p is at least 1, optionally 1, 2 or 3; and
at least one Metallocene is substituted with at least one substituent R¹ wherein R¹ is a group comprising an O, S, N or P atom.

Optionally, the compound of formula (I) has formula (Ia):

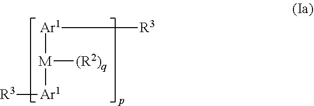

wherein:
M is a metal ion;
Ar¹ in each occurrence is a monocyclic or polycyclic aromatic or heteroaromatic group;
M and the two Ar¹ groups form the Metallocene;
at least one Ar¹ is substituted with at least one R¹ wherein R¹ is a group comprising an O, S, N or P atom;
R² is a group for satisfying the valency of M;
q is 0 or a positive integer, preferably 0 or 2;
R³ in each occurrence is independently H or a substituent; and
p is at least 1.

Exemplary Ar¹ groups include, without limitation, C₄-C₈ aromatic groups, i.e., cyclobutadiene, cyclopentadienyl, benzene, cycloheptatrienyl or cyclooctatetraene; and C₅ heteroaromatic groups, e.g., pyrrole, each of which may be unfused or fused to one or more further rings, preferably one or more benzene rings. Exemplary fused groups Ar¹ include benzocyclopentadienyl and fluorenyl.

Metallocene preferably comprises a metal M bound to two cyclopentadienyl groups Ar¹. Ar¹ may consist of the cyclopentadienyl group or the cyclopentadienyl may be fused to one or more further rings, preferably one or more aromatic rings, e.g. one or more benzene rings as in benzocyclopentadienyl or fluorenyl.

M may be Fe²⁺, Co²⁺, Cr²⁺, Ni²⁺ or V²⁺, preferably Fe²⁺. For each of these compounds, q is 0.

M may be Zr or Ti. For each of these compounds, q is 2 and R² may be any suitable group capable of bonding to Zr or Ti, for example methyl, ammonia, dialkylamines, phosphines, CO or halogen, e.g. Cl, such as in metallocene dihalides.

The two Ar¹ groups of the or each Metallocene may be linked—other than through M—by a divalent group, for example a C₁₋₆ alkylene or a group of formula Si(R³)₂ wherein R³ in each occurrence is independently a C₁₋₁₂ hydrocarbyl group, e.g. C₁₋₁₂ alkyl or phenyl. It will therefore be understood that compounds of formula (I) include ansa-metallocenes.

In a preferred embodiment, M and Ar¹ form ferrocene, i.e. M is Fe; each Ar¹ is cyclopentadienyl; and y is 0.

Preferably, R¹ is the only substituent of the Ar¹ groups.

Preferably, p is 1, 2 or 3, more preferably 1.

Compounds of formula (Ia) may be selected from formulae (Ib), (Ic) or (Id):

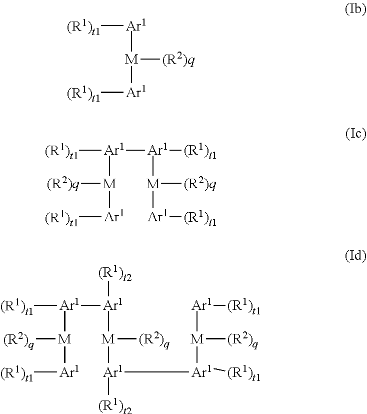

wherein t1 is 0, 1 or 2, preferably 0 or 1; t2 is 0 or 1, preferably 1; and at least one of t1 and/or t2 is at least 1.

In some embodiments, R¹ is a group of formula (II):

-A-B (II)
wherein A is a divalent group comprising O, S, N or P; and B is H, C₁-12 alkyl, optionally substituted aryl or optionally substituted heteroaryl.

Group A may comprise any group capable of binding to Pb. Exemplary groups A include, without limitation, ethers, thioethers, amines, phosphines, phosphoryl ethers, carbonates, carbamates, carboxylates, amides, thioamides, phosphonamides, thiocarboxylates, aminocarboxylates, and phosphocarboxylates. R1 may comprise only one group A. R¹ may comprise two or more groups A.

Exemplary groups A include groups of formulae (III) and (IV):

—(R⁵)_{f}—Z—(R⁵)g- (III)

—(R⁶⁰)ⱼ— (IV)
wherein:
R⁵ in each occurrence is independently a hydrocarbon group;
f and g are each independently 0 or 1;
R⁶ is a C₁-4 alkylene group, preferably ethylene;
j is 1-10; and
Z is O, S, COO, C(═S)O, C(═O)S, CONR⁴, CSNR⁴, OC(═O)O, OC(═O)NR⁴, OC(═O)PR⁴, NR⁴, PR⁴, —OP(═O)(OR⁴)—O—, or —NR⁴—P(═O)(NR⁴₂)—NR⁴—, wherein R⁴ is H, optionally substituted C₁₋₁₂ alkyl or optionally substituted phenyl.

Hydrocarbon groups R⁵ are preferably selected from C₁₋₆ alkylene; optionally substituted phenylene; and C₁₋₆ alkylene-phenylene.

A phenylene group of an R⁵ group may be unsubstituted or substituted with one or more substituents selected from C₁₋₆ alkyl.

In the case where R⁵ is C₁₋₆ alkylene-phenylene, the group Z may be bound to either the alkylene or the phenylene group.

A particularly preferred group A is —O—C(═O)—, which may be linked to Metallocene through the O atom or the C atom, preferably through the O atom.

B is preferably an optionally substituted aryl or heteroaryl, more preferably phenyl or a 5-membered heteroaromatic comprising one or more of N, S and O ring atoms, for example furan, thiophene, pyrrole, imidazoles and oxazole. Thiophene is particularly preferred.

Optional substituents of an optionally substituted alkyl or alkylene group as described anywhere herein include F, Cl, OR⁴ and NR⁴₂ wherein R⁴ is a C₁₋₆ alkyl.

Optional substituents of any optionally substituted aromatic or heteroaromatic group as described anywhere herein, including but not limited to substituents R³ of formula (Ia), include F, Cl, CN, NO₂, C₁₋₆ alkyl wherein one or more H atoms may be replaced with F, OR⁴ and NR⁴₂ wherein R⁴ is a C₁₋₆ alkyl.

Without wishing to be bound by any theory, an electron-rich heteroaryl group B may form a coordinate bond with Pb of the perovskite. This coordinate bond may be in addition to or instead of a bond of a group A. Accordingly, in some embodiments, R¹ may be a 5-membered heteroaromatic group of formula B as described above.

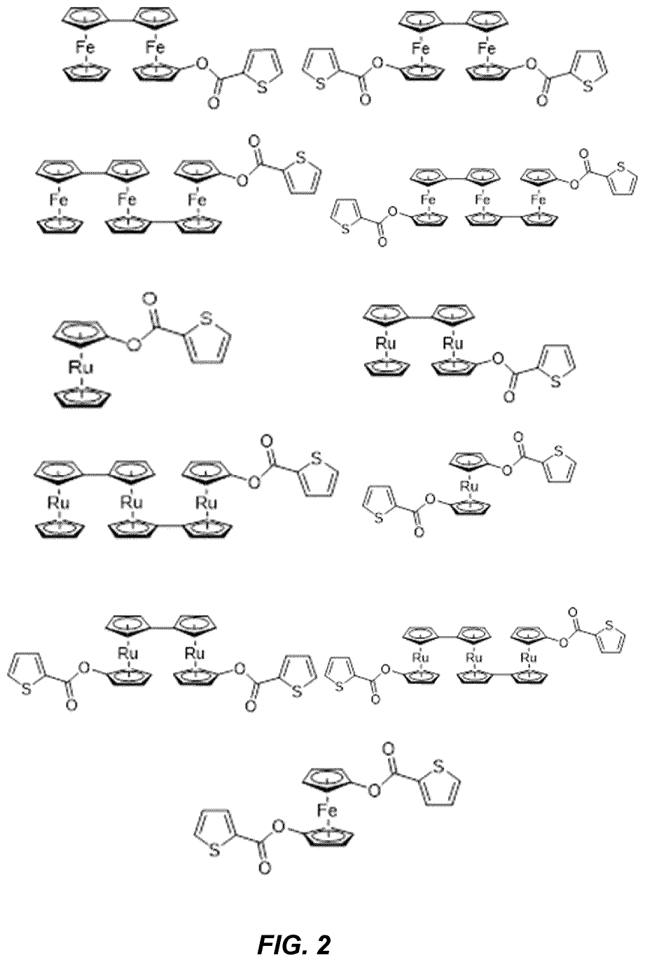

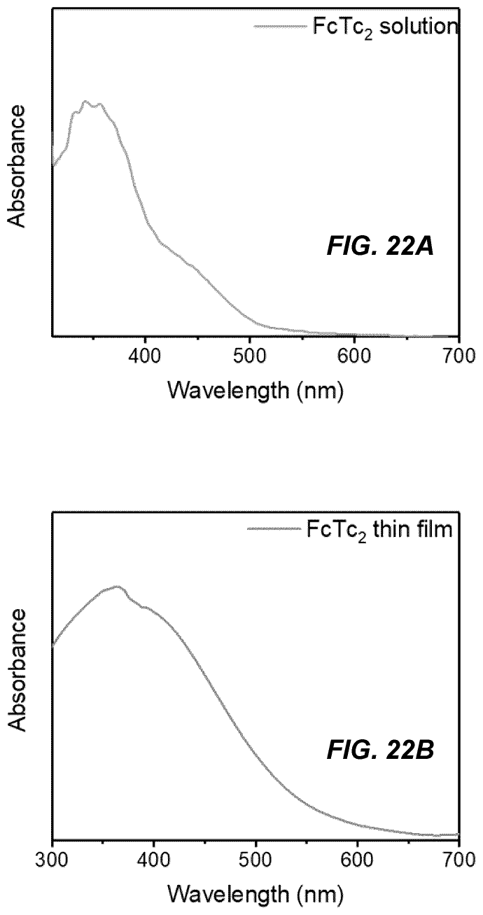

With reference to FIG. 2, structures of example compounds for the interface layer 108 are shown. In one specific example, interface layer 108 comprises ferrocenyl-bis-thiophene-2-carboxylate (FcTc₂) as the interface functionalization material to enhance the efficiency and stability of PVSCs. The ultraviolet-visible (UV-vis) absorption spectroscopy of FcTc₂ in solution and thin film form are provided in FIGS. 22A and 22B, respectively.

### Perovskite

The perovskites may be any material with the CatBX₃ crystal structure (perovskite structure, commonly referred to as the “ABX₃” structure), where Cat and B are cations and X is an anion. B is preferably Pb or Sn.

The perovskite is suitably a perovskite of formula CatPbX₃ or CatSnX₃ wherein Cat is a metal cation, an organic cation or a combination thereof and X is selected from at least one of I, Br and Cl.

Exemplary groups Cat include alkali metal cations, preferably Cs; ammonium cations, for example methylammonium; and amidinium ions, for example formamidinium.

Preferably, X includes two of I, Br and Cl.

Preferably, Cat comprises both a metal cation and an organic cation.

Preferably, Cat comprises two different organic cations.

Examples of perovskites suitable for use as a light-absorbing layer include: ammonium trihalogen plumbates such as CH₃NH₃PbI₃, CH₃NH₃PbCl₃, CH₃NH₃PbF₃ and CH₃NH₃PbBr₃; mixed-halide ammonium trihalogen plumbate perovskites with general formula CH₃NH₃Pb[Hal₁]₃₋ₓ[Hal₂]ₓ wherein [Hal₁] and [Hal₂] are independently selected from among F, Cl, Br and I with the proviso that [Hal₁] and [Hal₂] are non-identical and wherein 0<x<3, preferably wherein x is an integer (e.g. 1, 2 or 3, preferably 1 or 2); CsSnX₃ perovskites wherein X is selected from among F, Cl, Br and I, preferably I; organometal trihalide perovskites with the general formula (RNH₃)BX₃ where R is CH₃, CₙH₂ₙ or CₙH₂ₙ₊₁, n is an integer in the range 2≤n≤10, preferably 2≤n≤5, e.g. n=2, n=3, or n=4, most preferably n=2 or n=3, X is a halogen (F, I, Br or Cl), preferably I, Br or Cl, and B is Pb or Sn; and combinations thereof. In some examples, a perovskite composition of Csₓ(FA_{y}MA_{1-y})₁₋ₓPb(I_{z}Br_{1-z})₃, where x=(0˜0.95), y=(0˜1), z=(0˜1) is used, where MA and FA denote methylammonium and formamidinium, respectively.

### Photovoltaic Cell Formation

Photovoltaic cells as described herein may be formed by any method known to the skilled person. Preferably, the perovskite layer and the interface layer are each formed by depositing a solution comprising the perovskite and a solution comprising the metallocene. Suitable solvents for deposition of the perovskite layer include polar solvents such as DMF and DMSO. Preferably, the solvent for deposition of the metallocene is selected from chlorinated alkanes, for example chloroform; and benzene which is unsubstituted or substituted with one or more substituents selected from C₁-6 alkyl, C₁₋₆ alkoxy and chlorine, for example dichlorobenzene.

Solutions may be deposited by any method known to the skilled person, for example spin-coating, dip-coating, slot-die coating, doctor blade coating and bar coating.

### EXAMPLES

As described herein, the chemicals used include the following:
Perovskite precursors, Cesium iodide (CsI), formamidinium iodide (FAI), methylammonium chloride (MACI), and methylammonium bromide (MABr) purchased from Dysol (Australia).
Lead iodide (PbI₂), and lead bromide (PbBr₂) purchased from TCI (Japan).
C60, poly[bis(4-phenyl)(2,4,6-trimethylphenyl)amine] (PTAA) (Mn 6,000-15,000), methylammonium chloride (MACI) and bathocuproine (BCP, purity of 99.9%) purchased from Xi'an Polymer Light Technology Corporation (China).
Copper (I) thiophene-2-carboxylate (CuTC) was purchased from Sigma-Aldrich.
The solvents, including dimethylformamide (DMF), dimethyl sulfoxide (DMSO), isopropanol (IPA) and chlorobenzene (CB) were purchased from J&K (China) and used as received.
Acetonitrile (MeCN), dichloromethane (DCM), and hexane were purchased from Sigma-Aldrich and used as received.
High purity silver was purchased from commercial sources.
Glass substrates patterned with ITO (15 Ωsq⁻¹) were received from Mishi Tech. Co., Ltd. (China).

### FcTc₂—Synthesis 1

A solution of FcI₂ (1.0˜2.50 mmol), copper thiophene carboxylate (3.2˜9.5 mmol) and 9,10-dihydroanthracene (1.5˜5.5 mmol) in MeCN was stirred at 50˜90° C. for 1˜5 d. After cooling to room temperature, DCM was added and the green-blue reaction mixture was filtered over Celite. The solvent was then removed, and the crude mixture was dissolved in hexane and passed through a pad of silica (ca. 5 cm), with the desired product eluting in 50% DCM in hexane. After solvent removal, FcTc₂ was obtained as a yellow solid.

### FcTc₂—Synthesis 2

A solution of FcI₂ (0.70 g, 1.60 mmol), copper thiophene carboxylate (1.2 g, 6.32 mmol) and 9,10-dihydroanthracene (0.60 g, 3.33 mmol) in MeCN (30 mL) was stirred at 80° C. for 2 d. After cooling to room temperature, DCM (50 mL) was added and the green-blue reaction mixture was filtered over Celite. The solvent was then removed, and the crude mixture was dissolved in hexane and passed through a pad of silica (ca. 5 cm), with the desired product eluting in 50% DCM in hexane. After solvent removal, FcTc₂ was obtained as a yellow solid (0.17 g, 0.38 mmol, 24%). ¹H NMR (400 MHZ, CDCl₃, 298 K): δ (ppm) 7.78 (dd, J=3.7, 1.3 Hz, 2H, Thio-H), 7.56 (dd, J=5.0, 1.3 Hz, 2H, Thio-H), 7.06 (dt, J=5.0, 3.7 Hz, 2H, Thio-H), 4.68 (t, J=2.0 Hz, 4H, (CpTc)m-H), 4.10 (t, J=2.0 Hz, 4H, (CpTc)o-H). ¹³C {1H} NMR (100 MHZ, CDCl₃, 298 K): δ (ppm) 160.3 (2C, C═O), 134.2 (2C, ThioC-H), 133.3 (2C, ThioC-CO₂Fc), 133.2 (2C, ThioC-H), 128.0 (2C, ThioC-H), 116.6 (2C, CpC-O), 64.8 (4C, (CpTc)o-C—H), 62.2 (4C, (CpTc)m-C—H). MS ES+: m/z 437.9677 ([M]+ Calc.: 437.9683).

Fc₂Tc₂—Synthesis

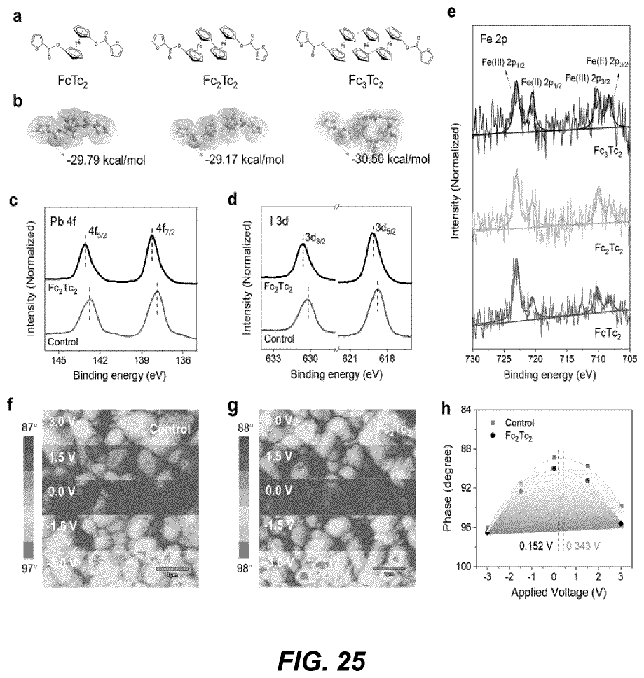

The structure of Fc₂Tc₂ is shown in FIG. 25.

Ferrocenyl-bis-thiophene-2-carboxylate (FcTc₂) was synthesized via the route as previously reported (Z. Li, B. Li, X. Wu. S. A. Sheppard, S. Zhang, D. Gao, N. J. Long and Z. Zhu, Science, 2022, 376, 416-420).

A solution of Fc₂I₂ (0.50 g, 0.80 mmol) (previously reported in M. S. Inkpen, S. Scheerer, M. Linseis, A. J. P. White, R. F. Winter, T. Albrecht and N. J. Long, Nat. Chem., 2016, 8, 825-830) and 9,10-dihydroanthracene (0.43 g, 2.41 mmol) in MeCN (100 mL) was sparged with nitrogen for 1 h, after which time CuTc (1.53 g, 8.04 mmol) was added. The green-brown reaction mixture was stirred at 80° C. for 2 d. The solvent was then removed, and the mixture was filtered in DCM over celite. The crude mixture was then dissolved in hexane and purified by silica plug (hexane→hexane/DCM (1:1) to yield Fc₂Tc₂ (60 mg, 0.10 mmol, 14%). ¹H NMR (400 MHZ, CDCl₃, 298 K): δ (ppm) 7.76 (dd, J=3.8, 1.3 Hz, 1H, Thio-H), 7.59 (dd, J=5.0, 1.3 Hz, 1H, Thio-H), 7.11 (dd, J=5.0, 3.8 Hz, 1H, Thio-H), 4.44 (t, J=1.9 Hz, 4H, (Cp-Cp)m-H), 4.39 (t, J=2.0 Hz, 4H, (CpTc)m-H), 4.16 (t, J=1.9 Hz, 4H, (Cp-Cp)o-H), 3.81 (t, J=2.0 Hz, 4H, (CpTc)o-H). ¹³C {1H} NMR (100 MHz, CDCl₃, 298 K): δ (ppm) 160.4 (2C, C═O), 134.2 (2C, ThioC—H), 133.5 (2C, ThioC-CO₂Fc), 133.0 (2C, ThioC—H), 127.9 (2C, ThioC—H), 116.3 (2C, CpC-O), 84.4 (2C, CpC-CCp), 69.2 (4C, (Cp-Cp)o-C—H), 67.7 (4C, (Cp-Cp)m-C—H), 64.5 (4C, (CpTc)o-C—H), 62.0 (4C, (CpTc)m-C—H). MS ES+: m/z 621.9653 ([M]+ Calc.: 621.9658).

Fc₃Tc₂—Synthesis

The structure of Fc₃Tc₂ is shown in FIG. 25.

MeCN (100 mL) was added to Fc₃I₂ (0.60 g, 0.74 mmol) (previously reported in M. S. Inkpen, S. Scheerer, M. Linseis, A. J. P. White, R. F. Winter, T. Albrecht and N. J. Long, Nat. Chem., 2016, 8, 825-830), CuTc (0.30 g, 1.58 mmol) and 9,10 dihydroanthracene (0.20 g, 1.11 mmol). The green-blue reaction mixture was stirred at 80° C. for 2d. The solvent was then removed, and the mixture was filtered in DCM over celite. The crude mixture was then purified by column chromatography on alumina(V), where Fc₃Tc₂ (20 mg, 0.03 mmol) eluted in 40% DCM in hexane. ¹H NMR (400 MHZ, CDCl₃, 298 K): δ (ppm) 7.73 (dd, J=3.7, 1.3 Hz, 2H, Thio-H), 7.58 (dd, J=5.0, 1.3 Hz, 2H, Thio-H), 7.11 (dt, J=5.0, 3.7 Hz, 2H, Thio-H), 4.34 (pseudo-t, J=2.0 Hz, 4H, (CpTc)m-H), 4.29 (pseudo-t, 4H, J=1.8 Hz, (Cp-Cp)o-H), 4.21 (pseudo-t, J=1.8 Hz, 4H, (Cp-Cp)o-H), 4.06 (pseudo-t, J=1.8 Hz, 4H, (Cp Cp)m H), 3.89 (pseudo-t, J=1.8 Hz, 4H, (Cp-Cp)m-H), 3.77 (t, J=2.0 Hz, 4H, (CpTc)o-H). ¹³C {1H} NMR (100 MHZ, CDCl₃, 298 K): δ (ppm) 160.3 (2C, C═O), 134.0 (2C, ThioC—H), 133.3 (2C, ThioC-CO₂Fc), 132.8 (2C, ThioC—H), 127.8 (2C, ThioC—H), 116.2 (2C, CpC-O), 85.3 (4C, CpC-CCp), 69.2 (4C, (Cp-Cp)m-C—H), 69.0 (4C, (Cp-Cp)o-C—H), 67.5 (4C, (Cp-Cp)m-C—H), 67.3 (4C, (Cp-Cp)o-C—H), 64.4 (4C, (CpTc)o-C—H), 61.8 (4C, (CpTc)m-C—H). MS ES+: m/z 805.9641 ([M]+ Calc.: 805.9634).

### Iodoferrocenes

To a solution of ferrocene (21.3 g, 114 mmol, 1 equiv.) in dry, degassed hexane (200 mL), tetramethylethylenediamine (TMEDA) (37.7 mL, 251 mmol, 2.2 equiv.) and the mixture was cooled to 0° C. To the cold solution, a bottle of nBuLi (2.5 M in hexane, 100 mL, 2.2 equiv.) was added via a canular, and the mixture was left to slowly warm to room temperature and stir overnight. The solution was cooled to −78° C., and a separation solution of iodine (43.5 g, 171 mmol, 1.5 equiv.) was prepared in diethyl ether (250 mL), which was then added to the cooled solution via a canular. The mixture was brought to 0° C., and water was added (100 mL), and then filtered over sand. The resulting filtrate was washed in brine (3×300 mL), dried over MgSO4, and then the solvent removed in vacuo to yield a dark red slurry. The monoferrocene, biferrocene and triferrocene products were separated using column chromatography (silica, hexane/toluene (6:4)). Monoferrocene fractions were dissolved in hexane and washed (10×0.5 M FeCl₃ (aq)) to remove ferrocene and iodoferrocene. The organic phase was then washed with water until colourless washings were apparent, then dried (MgSO4) and solvent removed to yield 1,1′-diiodoferrocene (FcI₂)—CB 597 F1 (2.73 g, 6.25 mmol, 6%). Biferrocene fractions were dissolved in DCM and washed (5×0.2 M FeCl₃ (aq)) to remove biferrocene and monoiodobiferrocenes. The organic phase was washed in water until colourless washings were apparent, then dried (MgSO4) and solvent removed to yield diiodobiferrocene (Fc2I2)—CB 597 F4+5 (1.09 g, 1.75 mmol, 2%).

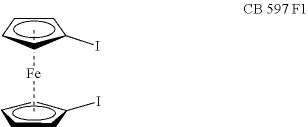

CB 597 F₁

CM 597 F₁

1H NMR (400 MHZ, CDCl₃, δ (ppm)): 4.37 (t, 4H, CpH, 3JHH=1.9 Hz), 4.18 (t, 4H, CpH, 3JHH=1.9 Hz). 13C NMR (101 MHz, CDCl₃, δ (ppm)): 77.7 (4C, CpC), 72.4 (4C, CpC), 40.4 (2C, C—I). HR-MS (ESI+): calculated: 437.8065, found: 437.8054.

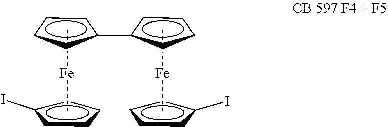

CB 597 F₄+F₅

1H NMR (400 MHZ, CDCl₃, δ (ppm)): 4.36 (pseudo t, 4H, CpH), 4.24 (pseudo t, 4H, CpH), 4.16 (pseudo t, 4H, CpH), 3.98 (pseudo t, 4H, CpH). 13C NMR (101 MHZ, CDCl₃, δ (ppm)): 84.8 (2C, CpC), 75.9 (2C, CpC), 71.1 (4C, CpC), 70.2 (4H, CpC), 69.7 (4H, CpC), 40.9 (2C, C—I). HR-MS (ESI+): calculated: 621.8040, found: 621.8026 (some triferrocene from mass spectrum, although no evidence in NMR).

### Ferrocene Thiocarboxylates

A solution of 1,1′-diiodoferrocene (CB 597 F1) (721 mg, 1.60 mmol, 1 equiv.) was prepared in lab grade acetonitrile (30 mL) and was degassed for 10 minutes. The addition of copper (II) thiophenecarboxylate (1.24 g, 6.32 mmol, 3.95 equiv.) and 9,10-dihydroanthracene (620 mg, 3.33 mmol, 2 equiv.) followed and the mixture was heated to 80° C. and left overnight. After 24 hours, the mixture showed no diiodoferrocene by 1H NMR, and so DCM (50 mL) was added and the green solution was allowed to cool to room temperature. The solution was filtered through celite and purified using column chromatography (silica, hexane→hexane/DCM (1:1)) to yield the products ferrocene thiophene carboxylate (FcTc)—CB 598 F2 (29 mg, 0.091 mmol, 6%) and ferrocene bis(thiophene carboxylate) (FcTc2)—598 F3 (109 mg, 0.249 mmol, 16%) as respective fractions.

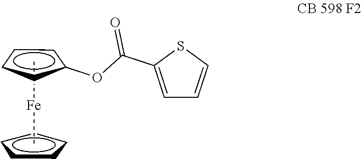

CB 598 F₂

1H NMR (400 MHZ, CDCl₃, δ (ppm)): 7.89 (dd, 1H, C—H, JHH=3.8 Hz, 1.3 Hz), 7.63 (dd, 1H, C—H, JHH=5.0 Hz, 1.3 Hz), 7.16 (dd, 1H, C—H, JHH=5.0 Hz, 3.8 Hz), 4.56 (t, 2H, CpH, 3JHH=2.0 Hz), 4.26 (s, 5H, CpH), 4.00 (t, 2H, CpH, 3JHH=2.0 Hz).

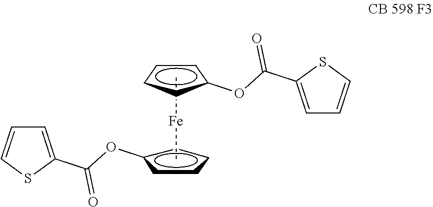

1H NMR (400 MHZ, CDCl₃, δ (ppm)): 7.78 (d, 2H, C—H, JHH=3.7 Hz), 7.56 (d, 2H, C—H, JHH=5.0 Hz), 7.06 (t, 2H, C—H, JHH=4.3 Hz), 4.68 (pseudo t, 4H, CpH), 4.10 (pseudo t, 2H, CpH).

### Carboxaldehyde Ferrocenes

To a suspension of ferrocene (5.0 g, 27 mmol, 1.0 equiv.) in diethyl ether (60 mL), TMEDA (10.1 mL, 67.5 mmol, 2.5 equiv.) was added, and the resulting solution cooled to −78° C. To the cold solution, nBuLi (26 mL, 64.8 mmol, 2.4 equiv.) was added and the resulting solution allowed to warm to room temperature and stir overnight. The solution was then cooled again to −78° C. and dimethyl formamide (6.27 mL, 81 mmol, 3.0 equiv.) and the solution went darker in colour. Hydrochloric acid (2.5 M, 205 mL) was added and diethyl ether was removed in vacuo. The product was extracted in DCM (100 mL×4), washed (1×2.5 M HCl; 1×H2O) and dried (Na2SO4) and solvent removed in vacuo. The monocarboxylate and dicarboxylate products were separated using column chromatography (silica, hexane/ethyl acetate (1:1→1:3)) to yield carboxaldehyde ferrocene CB 599 F2 (174 mg, 0.812 mmol, 3%) and 1,1′-dicarboxaldehyde ferrocene CB 599 F3 (4.60 g, 19.0 mmol, 71%).

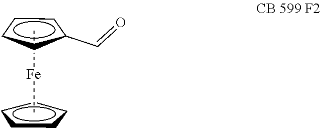

CB 599 F₂

1H NMR (400 MHZ, CDCl₃, δ (ppm)): 9.96 (s, 1H, HC═O), 4.80 (pseudo t, 2H, CpH), 4.61 (pseudo t, 2H, CpH), 4.28 (s, 5H, CpH). 13C NMR (101 MHZ, CDCl₃, δ (ppm)): 193.7 (C═O), 73.4 (CpC), 69.8 (CpC). HR-MS (ESI+): calculated: 215.0159, found: 215.0168.

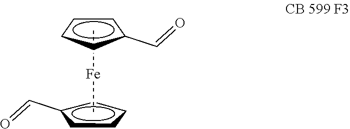

CB 599 F₃

1H NMR (400 MHZ, CDCl₃, δ (ppm)): 9.94 (s, 2H, HC═O), 4.88 (pseudo t, 4H, CpH), 4.67 (pseudo t, 4H, CpH). 13C NMR (101 MHZ, CDCl₃, δ (ppm)): 193.0 (C═O), 80.4 (CpC), 74.3 (CpC), 71.0 (CpC). HR-MS (ESI+): calculated: 243.0108, found: 243.0102.

### Thiopheneyl Ferrocene

### Monosubstitution Preference

To a suspension of aluminium trichloride (717 mg, 5.38 mmol, 2.0 equiv.) suspended in DCM (15 mL), 2-thiophenecarbonyl chloride (575 μL, 5.38 mmol, 2.0 equiv.) was added followed by the addition of ferrocene (500 mg, 2.69 mmol, 1.0 equiv.) where the orange solution turned deep blue. After 1 hour of stirring at room temperature, the mixture was poured onto ice and stirred for 30 minutes until fully melted. NaOH (aq. 25%) was added until neutralisation was achieved, and then the product was extracted in DCM (3×75 mL), dried (Na2SO4), and the solvent removed in vacuo to yield a dark red oil. Purification was achieved using column chromatography (silica, hexane/ethyl acetate (95:5→50:50 gradient) to yield (Thiopheneyl) ferrocene CB 601 F1 (569 mg, 1.92 mmol, 71%) and 1,1′-bis(thiopheneyl) ferrocene (2a) CB 601 F2 (Combined with CB 604 F3-F4 and purified once more to give 137 mg of product (CB 601+604) (69 g, 0.17 mmol, 6%).

### Disubstitution Preference

To a suspension of aluminium trichloride (3.58 g, 26.9 mmol, 5.0 equiv.) suspended in DCM (40 mL), 2-thiophenecarbonyl chloride (2.88 mL, 26.9 mmol, 5.0 equiv.) was added followed by the addition of ferrocene (1 g, 5.38 mmol, 1.0 equiv.) where the orange solution turned deep blue. After stirring at room temperature overnight, the mixture was poured onto ice and stirred for 30 minutes until fully melted. NaOH (aq. 25%) was added until neutralisation was achieved, and then the product was extracted in DCM (3×75 mL), dried (Na2SO4), and the solvent removed in vacuo to yield a dark red oil. Purification was achieved using column chromatography (silica, hexane/ethyl acetate (95:5→50:50 gradient) to yield 1,1′-bis(thiopheneyl) ferrocene (2a) CB 608 F5 (1.20 g, 2.95 mmol, 55%). CB 608 F5 could benefit from further purification-one more column.

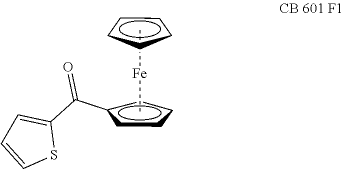

CB 601 F₁

1H NMR (400 MHZ, CDCl₃, δ (ppm)): 7.93 (dd, 1H, ArH, JHH=3.8 Hz, 1.2 Hz), 7.62 (dd, 1H, ArH, JHH=4.9 Hz, 1.2 Hz), 7.16 (m, 1H, ArH), 5.03 (t, 2H, CpH, 3JHH=2.0 Hz), 4.60 (t, 2H, CpH, 3JHH=2.0 Hz), 4.23 (s, 5H, CpH). 13C NMR (126 MHZ, CDCl₃, δ (ppm)): 189.7 (C═O), 167.0 ((O═C)C), 131.9 (ArC), 131.8 (ArC), 127.8 (ArC), 72.5 (CpC), 71.1 (CpC), 70.5 (CpC). HR-MS (ESI+): calculated: 297.0033, found: 297.0037.

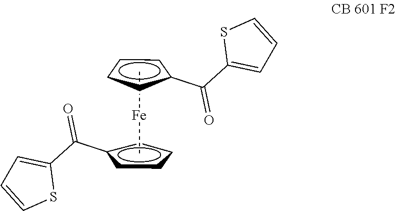

CB 601 F₂

1H NMR (400 MHZ, CDCl₃, δ (ppm)): 7.84 (d, 2H, ArH, JHH=3.8 Hz), 7.63 (d, 2H, ArH, JHH=4.9 Hz), 7.13 (t, 2H, ArH, JHH=4.3 Hz), 5.06 (pseudo t, 4H, CpH), 4.60 (pseudo t, 4H, CpH). 13C NMR (101 MHZ, CDCl₃, δ (ppm)): 188.4 (C═O), 143.9 (ArC), 132.7 (ArC), 132.2 (ArC), 128.0 (ArC), 80.5 (CpC), 74.8 (CpC), 72.8 (CpC). HR-MS (ESI+): calculated: 406.9848, found: 406.9863.

### (Furyl)Ferrocene

To a suspension of aluminium trichloride (1.79 g, 13.44 mmol, 5.0 equiv.) suspended in DCM (20 mL), 2-furoyl chloride (1.33 mL, 13.44 mmol, 5.0 equiv.) was added followed by the addition of ferrocene (500 mg, 2.69 mmol, 1.0 equiv.) where the orange solution turned deep blue. After stirring at room temperature overnight, the mixture was poured onto ice and stirred for 30 minutes until fully melted. NaOH (aq. 25%) was added until neutralisation was achieved, and then the product was extracted in DCM (3×75 mL), dried (Na2SO4), and the solvent removed in vacuo to yield a dark red oil. Purification was achieved using column chromatography (silica, hexane/ethyl acetate (95:5→50:50 gradient) to yield 1,3-bis(furyl) ferrocene CB 605 F3 (90 mg, 0.32 mmol, 12%) and 1,1′-bis(furyl) ferrocene (2b) CB 605 F5 (198 mg, 0.53 mmol, 20%). Could benefit from a further column, some minor impurities present.

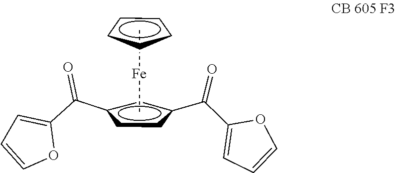

CB 605 F₃

1H NMR (400 MHZ, CDCl₃, δ (ppm)): 7.76 (s, 1H, ArH), 7.65 (dd, 2H, ArH, JHH=5.8 Hz, 3.7 Hz), 7.40 (d, 1H, ArH, JHH=3.7 Hz), 6.69 (s, 1H, ArH), 5.28 (t, 1H, CpH, JHH=2.0 Hz), 4.71 (t, 2H, CpH, JHH=2.0 Hz), 4.23 (s, 5H, CpH). 13C NMR (101 MHz, CDCl₃, δ (ppm)): 147.3 (ArC), 120.4 (ArC), 120.3 (ArC), 117.0 (ArC), 113.0 (ArC), 73.5 (CpC), 71.3 (CpC), 70.6 (CpC). HR-MS (ESI+): calculated: 375.0320, found: 375.0324.

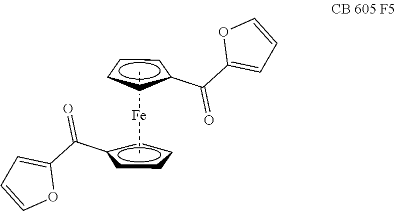

CB 605 F₅

1H NMR (400 MHZ, CDCl₃, δ (ppm)): 7.55 (s, 2H, ArH), 7.26 (s, 2H, ArH), 6.54 (s, 2H, ArH), 5.16 (pseudo t, 4H, CpH), 4.57 (pseudo t, 4H, CpH). 13C NMR (101 MHZ, CDCl₃, δ (ppm)): 145.8 (ArC), 117.3 (ArC), 112.3 (ArC), 74.4 (CpC), 72.6 (CpC). HR-MS (ESI+): calculated: 375.0320, found: 375.0335.

### (Benzoyl)Ferrocene

To a suspension of aluminium trichloride (1.79 g, 13.44 mmol, 5.0 equiv.) suspended in DCM (20 mL), benzoyl chloride (1.56 mL, 13.44 mmol, 5.0 equiv.) was added followed by the addition of ferrocene (500 mg, 2.69 mmol, 1.0 equiv.) where the orange solution turned deep blue. After stirring at room temperature overnight, the mixture was poured onto ice and stirred for 30 minutes until fully melted. NaOH (aq. 25%) was added until neutralisation was achieved, and then the product was extracted in DCM (3×75 mL), dried (Na2SO4), and the solvent removed in vacuo to yield a dark red oil. Purification was achieved using column chromatography (silica, hexane/ethyl acetate (95:5→50:50 gradient) to yield 1,1′-bis(benzoyl) ferrocene (2d) CB 606 F3 (745 mg, 1.89 mmol, 70%).

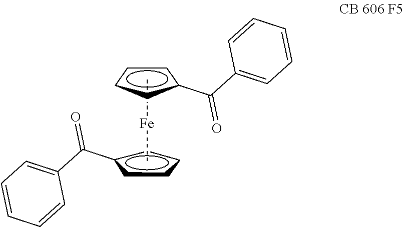

CB 606 F₅

1H NMR (400 MHZ, CDCl₃, δ (ppm)): 7.78 (d, 4H, ArH, JHH=7.6 Hz), 7.54 (t, 2H, ArH, JHH=7.5 Hz), 7.42 (t, 4H, ArH, JHH=7.6 Hz), 4.91 (pseudo t, 4H, CpH), 4.58 (pseudo t, 4H, CpH). 13C NMR (101 MHZ, CDCl₃, δ (ppm)): 197.9 (C═O), 139.3 (ArC), 132.1 (ArC), 128.5 (ArC), 128.3 (ArC), 79.6 (CpC), 74.8 (CpC), 73.3 (CpC). HR-MS (ESI+): calculated: 395.0730, found: 395.0734.

### Example Solar Cell—General Method

Solar cells were prepared according to the following method:
Glass/ITO substrates (10˜45 Ωsq⁻¹) were sequentially cleaned by sonication with detergent, deionized water, acetone and isopropyl alcohol for 5˜30 min, respectively.
Then, the glass/ITO substrates were dried at 80˜120° C. in an oven, and then were treated with oxygen plasma for 5˜40 minutes and finally transferred into a N₂-filled glovebox before use.
A PTAA solution was prepared with a concentration of 0.6˜4.1 mg mL⁻¹ in solvent. 15˜65 μL of the as-prepared PTAA solution was spin-coated onto the ITO substrates at 3500˜7000 rpm for 18˜50 s and the substrates were subsequently annealed at 75˜130° C. for 5˜20 min.
A 1.2˜2.2 M perovskite precursor solution was prepared by mixing CsI, FAI, MABr, PbI₂ and PbBr₂ in 1 mL DMF:DMSO (3˜15:1/v:v) mixed solvent to give a perovskite with a chemical formula of Csₓ(FA_{y}MA_{1-y})₁₋ₓPb(I_{z}Br_{1-z})₃, where x=(0˜0.95), y=(0˜1), z=(0˜1), including a 3˜15 mol % of excess PbI₂ relative to FAI.
Then 9.2˜36.0 mol % MACI was added to the perovskite precursor solution and stirred for 0.5˜12 h. 30˜100 μL perovskite solutions were spin-coated onto glass/ITO/HTL at 350˜1800 rpm for 5˜20 s, subsequently at 3500˜7000 rpm for 30˜60 s.
150˜300 μL solvent was slowly dripped onto the center of film at 5˜18 s before the end of spin-coating.
The as-prepared perovskite films were subsequently annealed on a hotplate at 90˜150° C. for 10˜60 min.

To form the interface layer:
FcTc₂ powder was prepared and dissolved in solvent at a concentration of 0.3˜2.2 mg mL⁻¹.
The as-prepared yellowish solution was stirred at room temperature (20-25° C.) until the solution became clear. The solution was then transferred to a N₂-filled glovebox before use.
60˜180 μL of FcTc₂ solution was spin-coated on top of the as-prepared perovskite at 4000˜6000 rpm for 10˜25 s, and then transferred to the hotplate and annealed at 85˜135° C. for 1˜10 min. The spin-coating processes were all conducted at room temperature (20-25° C.) in a N₂-filled glovebox with the contents of O₂ and H₂O<10 ppm.

To complete the device:
10˜30 nm C60 was thermally evaporated at a rate of 0.3˜1.5 Å s⁻¹, 4˜10 nm under high vacuum (<4×10⁻⁶ Torr).
BCP was thermally evaporated at a rate of 0.2˜1.2 Å s⁻¹ under high vacuum (<4×10-6 Torr).
70˜120 nm silver electrode was thermally evaporated at a rate of 0.5˜3.0 Å s⁻¹ under high vacuum (<4×10⁻⁶ Torr).

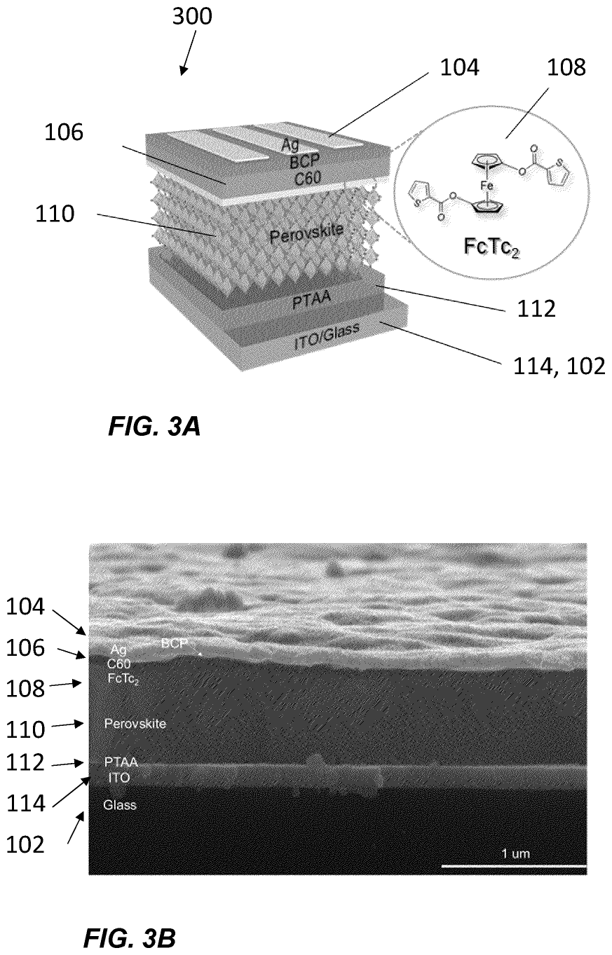

FIG. 3A shows a schematic illustration of the solar cell 300 according to this example.

### Solar Cell Example 1

A solar cell having a perovskite composition of CS_{0.05}(FA_{0.98}MA_{0.02})_{0.95}Pb(I_{0.98}Br_{0.02})₃ is prepared according to the general method as follows.
Glass/ITO substrates (15 Ωsq⁻¹) were sequentially cleaned by sonication with detergent, deionized water, acetone and isopropyl alcohol for 20 min, respectively.
Then, the glass/ITO substrates were dried at 100° C. in an oven, and then were treated with oxygen plasma for 10 minutes and finally transferred into a N₂-filled glovebox before use.
A PTAA solution was prepared with a concentration of 2.2 mg mL⁻¹ in chlorobenzene (CB). 35 μL of the as-prepared PTAA solution was spin-coated onto the ITO substrates at 6000 rpm for 30 seconds and the substrates were subsequently annealed at 100° C. for 10 minutes.
The 1.73 M perovskite precursor solution was prepared by mixing CsI, FAI, MABr, PbI₂ (5 mol % excess relative to FAI) and PbBr₂ in 1 mL DMF:DMSO (5:1/v:v) mixed solvent to give a precursor with a chemical formula of CS_{0.05}(FA_{0.98}MA_{0.02})_{0.95}Pb(I_{0.95}Br_{0.02})₃. Then 15.5 mol % MACI was added to the perovskite precursor solution and stirred for 2 hours.
60 μL perovskite solutions were spin-coated onto glass/ITO/HTL at 1000 rpm for 10 seconds, and subsequently at 5000 rpm for 40 seconds.
250 μL CB was slowly dripped onto the center of the film at 12 seconds before the end of spin-coating.
The as-prepared perovskite films were subsequently annealed on a hotplate at 110° C. for 20 minutes.

To form the interface layer:
For the Fc-treated (FcTc₂, Fc₂Tc₂, and Fc₂Tc₂) devices, the Fc compound was prepared and dissolved in CB at a concentration of 1 mg mL⁻¹. Where other concentrations are used, this is stated.
The as-prepared yellowish solution was stirred at room temperature (20-25° C.) until the solution became clear. The solution was then transferred to a N₂-filled glovebox before use.
100 μL of FcTc₂ solution was spin-coated on top of the as-prepared perovskite at 5000 rpm for 20 seconds, and then transferred to the hotplate and annealed at 100° C. for 2 min.
The spin-coating processes were all conducted at room temperature (20-25° C.) in a N₂-filled glovebox with the contents of O₂ and H₂O<10 ppm.

To complete the device:
20 nm C60 was thermally evaporated at a rate of 0.5 Å s⁻¹ under high vacuum (<4×10⁻⁶ Torr).
6 nm BCP was thermally evaporated at a rate of 0.5 Å s⁻¹, under high vacuum (<4×10⁻⁶ Torr).
100 nm silver electrode was thermally evaporated at a rate of 1.0 Å s⁻¹ under high vacuum (<4×10⁻⁶ Torr).
The device area was defined and characterized as 0.08 cm² by metal shadow mask.

The same procedure was used to form cells in which the interface layer is Fc₂Tc₂, or Fc₃Tc₂

### Comparative Solar Cell 1

A solar cell was formed as described for Solar Cell Example 1 but without an interface layer.

The performances of Solar Cell Example 1 and Comparative Solar Cell 1 were compared.

### Experimental Parameters and Measurements

Device performance was characterized according to the following methods:
XRD data were collected in the reflection mode at room temperature on a Philips X'Pert diffractometer equipped with a CPS 180 detector using monochromated Cu—Kα (λ=1.5418 A) radiation.
The surface and cross-section morphology of the perovskite films were acquired by SEM (QUATTROS, Thermal Fisher Scientific).
XPS measurements were conducted by AXIS Supra XPS system. KPFM data were acquired via Bruker Dimension Kelvin probe force microscopy in Potential Channel equipped with PFQNE-AL probe.
AFM-based characterizations (AFM, KPFM and EFM) were conducted through Bruker Dimension ICON under ambient conditions, and Ti/Ir coated silicon tips (ASYELELC-01-R2) with a resonance frequency at ˜58-97 KHz were used in Scanning Kelvin Probe Microscopy (SKPM) and Electrostatic Force Microscopy (EFM) imaging.
PTIR measurements were carried out by a commercial Bruker NanoIR2-FS setup (testing range from 900 to 1800 cm⁻¹) consisting of an AFM microscope operating in contact mode.
FTIR spectroscopy was conducted by Fourier transform infrared spectrometer (Tensor 27, Germany Bruker).
The steady-state and time-resolved PL spectra were obtained by Edinburgh FLS980 applied with an excitation wavelength of 485 nm.
The film thickness of perovskite was obtained by DektakXT stylus profiler.
UV-vis absorptions were measured by a UV-vis spectrometer (PerkinElmer model Lambda 2S).
ToF-SIMS measurements were performed using a TOF-SIMS V instrument (IONTOF GmbH, Cameca IMS 4F).
The J-V characteristics of photovoltaic devices was conducted in a N₂-filled glovebox at room temperature by using a Xenon lamp solar simulator (Enlitech, SS-F5, Taiwan). The power of the light was calibrated to 100 mW cm⁻² by a silicon reference cell (with a KG2 filter). Before J-V measurements, a 120-nm thick magnesium fluoride layer was deposited on the back of ITO substrate for transmittance enhancement. All the devices were measured using a Keithley 2400 source meter under a sweep mode of reverse scan (from 1.20 V to −0.01 V) and forward scan (from −0.01 V to 1.20 V) with the scan rate of 0.01 V s⁻¹, and the delay time was 10 ms. No preconditioning was needed before the measurement. The active area was defined and characterized as 0.0414 cm² for small-area and 1.00 cm² for centimeter-area by metal shadow mask. The stabilized power output was conducted by monitoring the stabilized current density output at the maximum-power-point (MPP) bias (extracted from the reverse scan J-V curves).
EQE measurements were carried out by a QE-R EQE system (Enlitech, Taiwan). Highly sensitive EQE was measured by an integrated system (PECT-600, Enlitech, Taiwan), where the photocurrent was amplified and modulated by a lock-in instrument.
Electroluminescence (EL) quantum efficiency (EQEEL) was conducted by applying external voltage/current sources through the instrument (ELCT-3010, Enlitech, Taiwan).
¹H and ¹³C{¹H} NMR spectra were recorded on a Bruker Avance 400 MHz spectrometer and referenced to the residual solvent peaks of either CDCl₃ at 7.26 and 77.2 ppm or CD₂Cl₂ at 5.32 or 54.0 ppm, respectively. 1H-NMR spectra were fully assigned using 2D correlation spectroscopy.
Coupling constants are measured in Hz.
For peak force infrared (PFIR) imaging, an atomic force microscope (AFM) was operated under the peak force tapping mode using a Bruker NanoIR2-FS setup (testing range from 900 to 1800 cm⁻¹) operating in contact mode, allowing for the tip-sample distance to be known during the operation. During IR image acquisition, where the IR source wavelength was fixed at 1480 cm⁻¹ and the AFM tip was scanned across the sample surface, chemical mapping of high spatial resolution was created, while providing high-quality IR spectroscopy and chemical imaging for the organic components in the perovskite films. The phase-locked loop synchronized the laser pulse with each peak force tapping cycle. The four-quadrant photodiode read and digitized the vertical deflection produced by laser-induced contact resonance. The PFIR signal was obtained from the amplitude of the fast Fourier transform of the contact resonance. For PFIR images, the scan area was 10×10 μm2, and the scan rate was 0.5 Hz. The resonant frequency of the AFM tip was 264 kHz. Laser output power was dependent on this selected frequency.

As described herein, the device stability was tested according to the following methods:
The long-term operational stability of the PVSCs was conducted by applying the PVSCs under 1 sun equivalent LED lamp under N₂-filled glovebox (with the contents of O₂ and H₂O<10 ppm) at room temperature. The PVSCs were biased at maximum-power-point (MPP) voltage and the PCE was measured with an MPP-tracking routine by using a multi-potentiostat (CHI1040C, CH Instruments, Inc.). A cooling system was applied to keep the device at 25° C. During the MPP test, the current density-voltage (J-V) curves of the devices were obtained every 12 h to get the proper loads for the MPP.
The heat stability was conducted by applying the PVSCs on the hotplate (HS 7, IKA) maintained at 85° C. in a N₂-filled glovebox (with the contents of O₂ and H₂O<10 ppm), the PCE evolutions of the devices were obtained through the periodical J-V measurement.
The water and oxygen stability test was carried out by applying the PVSCs in ambient air (40-50% RH) without any light illumination, the PCE evolutions of the devices were obtained through the periodical J-V measurement.

For the density functional theory (DFT) calculations, geometry optimizations and frequencies of the ground state for the FcTc2, Fc2Tc2 and Fc3Tc2 molecules were carried out with B3LYP functional combined with 6-31g (d, p) basis set using the Gaussian16 package (version CO1). The intramolecular electrostatics interactions were described by DFT-D3 (Grimme 2006). The electrostatic potential (ESP) analysis was carried out with MULTIWFN software. The van der Waals surface (vdW) isosurface was set equal to 0.001 e/bohr³.

For the stability tests following the IEC61215:2016 standard, the PVSCs were encapsulated by polyisobutylene (PIB) based polymer (PVS 101®) and covered with 1.1-mm glass sheets on both sides of the devices.

The damp heat test was conducted by keeping the encapsulated devices maintained at 85° C./85% RH in the environment test chamber (EL-10KA, ESPEC, Japan) for 1000 h.

For the temperature cycling tests, the PVSCs were placed in the environment test chamber (EL-04KA, ESPEC, Japan), with the temperature cycling between −40±2° C. to 85±2° C. The temperature change rate between the −40° C. and 85° C. was set to not exceeded 100° C./h, and the temperature maintained stable for at least 15 min at the temperature point of −40° C. and 85° C., respectively.

### Results

FIG. 3B shows a scanning electron microscope image of the different layers of Solar Cell Example 1.

FIG. 3C shows time-of-flight secondary-ion mass spectrometry (ToF-SIMS) data, which demonstrates that the majority of the FcTc₂ (see trace for Fe⁺) is located on the surface of the perovskite film, between the ETL 106 and the perovskite layer 110. The FcTc₂ is deposited on the perovskite film at a stage where the perovskite crystallization has been completed. Moreover, in theory, the FcTc₂ molecule is too large to be incorporated into the perovskite lattice. The existence of the Fe signal in the perovskite bulk in the ToF-SIMS data is because the specific ion signal cannot suddenly disappear, but rather gradually decreases (the same signal tailing is also seen for Ag, Pb etc.). X-ray diffraction (XRD), top-view SEM and UV-vis absorption spectroscopy measurements were made to study the crystallinity, morphology and optical absorption of perovskite films with and without FcTc₂ treatment. All the samples showed no obvious change between control device and that with a functional layer 108, indicating that the FcTc₂ compound does not affect the crystallization and light-harvesting properties of perovskite films.

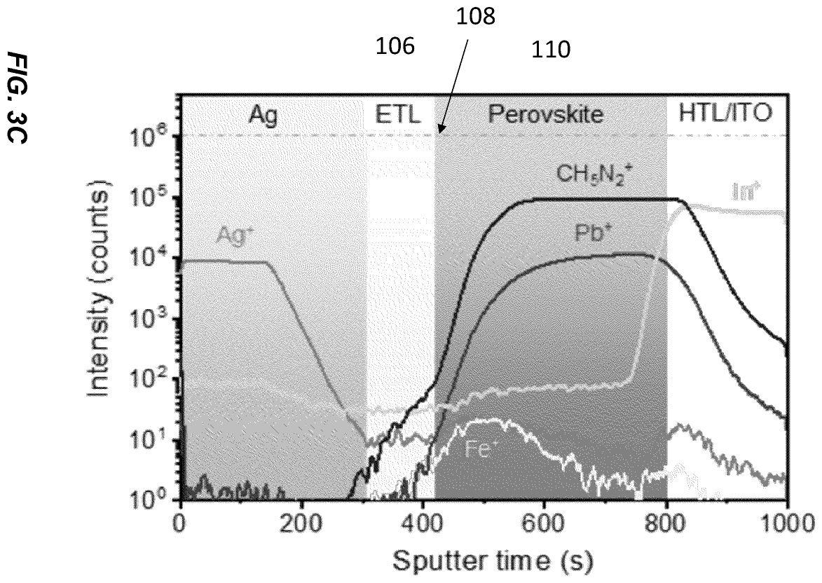

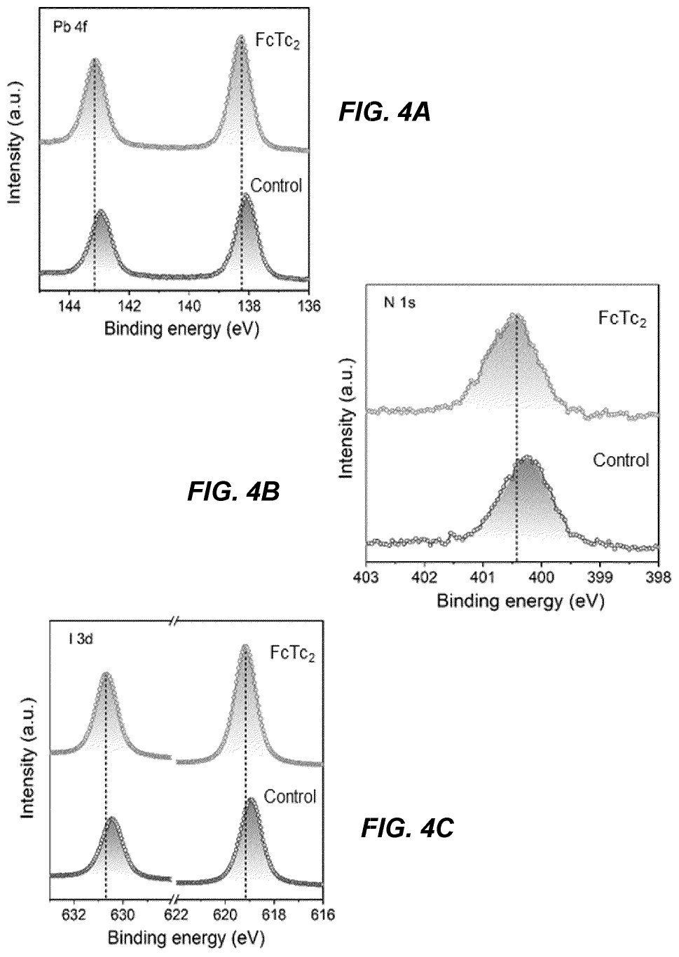

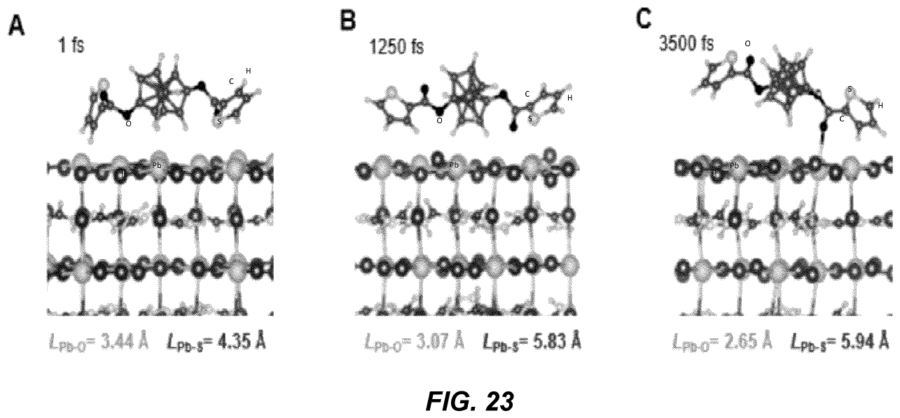

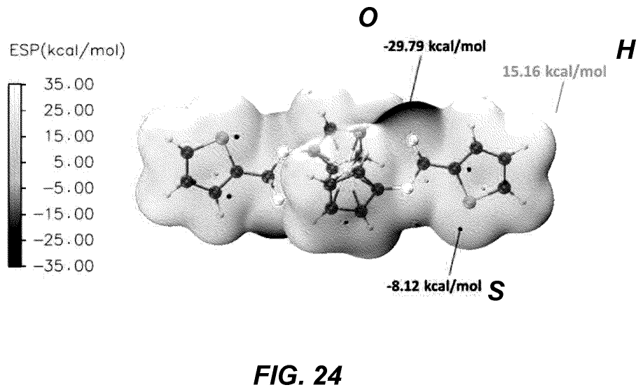

To study how FcTc₂ interacts with perovskite, X-ray photo-electron spectroscopy (XPS) measurements were conducted. Results are shown in FIG. 4. The binding energies corresponding to the Pb 4f (FIG. 4A), I 3d (FIG. 4B) and N 1s (FIG. 4C) core levels of the FcTc₂-treated perovskite devices all shift marginally to higher values compared with the control sample. This suggests enhanced binding of both anions and cations on the perovskite surface (which may be due to strong binding between surface ions and FcTc₂ interface layer 108). This binding is discussed further below with reference to FIGS. 23 and 24.

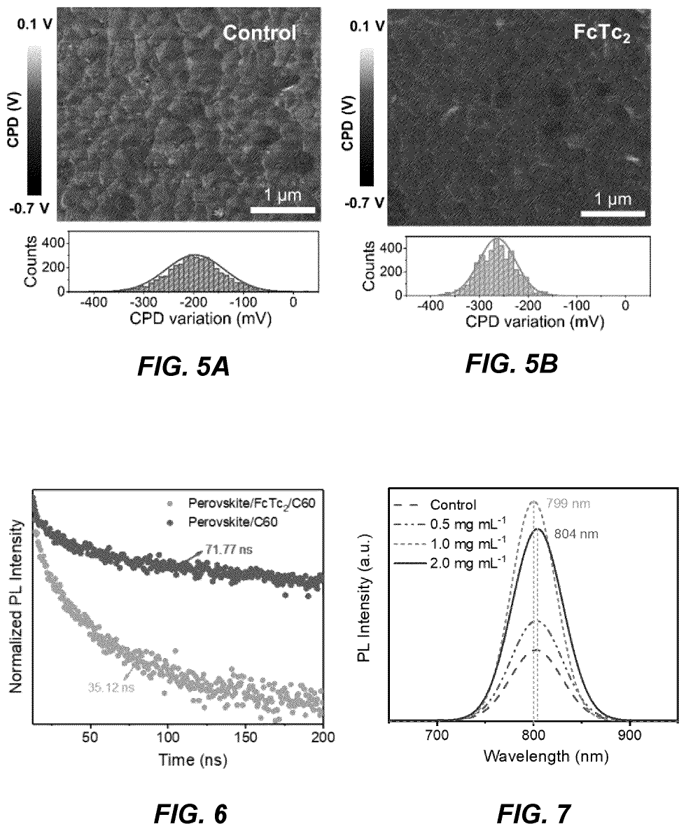

To study the effect of FcTc₂ on the electrical properties of perovskite films, Kelvin probe force microscopy (KPFM) measurements were conducted to examine the surface potential of the films. Results are shown in FIG. 5.

The perovskite film functionalized by FcTc₂ (FIG. 5B) exhibits a decreased contact potential (around 50 mV) relative to that of the control sample (FIG. 5A), suggesting direct interaction and surface charge transfer between the FcTc₂ interface layer 108 and perovskite layer 110. Moreover, FcTc₂-functionalized perovskite displays a smaller potential distribution with surface potential difference (˜150 mV) than that of the control sample (˜250 mV). The uniform distribution of surface contact potential is beneficial for effective charge carrier extraction and nonradiative recombination inhibition at perovskite grain boundaries.

Time-resolved photoluminescence (TRPL) spectra were measured to evaluate the non-radiative recombination of perovskite films, and results of the fitting parameters are shown in FIG. 6. The TRPL profiles were fitted with biexponential decays with a fast and slow component based on the equation:

$${τ}_{avg} = ( {A}_{1} {{τ}_{1}}^{2} + {A}_{2} {{τ}_{2}}^{2} ) / ( {A}_{1} {τ}_{1} + {A}_{2} {τ}_{2} ) ,$$

where parameters A₁ and A₂ are the amplitude fraction for each decay component, and τ₁, τ₂ represent the time constants of the two types of decay: τ₁ is the time constant for the fast decay component (related to the charge trapping process) and τ₂ is the time constant for the slow decay component (related to the charge de-trapping or carrier recombination process).

The carrier lifetime was significantly increased from 1166.74 ns to 2159.22 ns with the incorporation of FcTc₂ (see also Table 1 below). Carrier lifetime is defined as the average time it takes for a minority carrier to recombine. The increased carrier lifetime seen in Table 1 is consistent with the enhanced steady-state PL intensity shown in FIG. 7, which shows the photoluminescence intensity for devices with no interface layer, an interface layer having an FcTc₂ concentration of 0.5 mg mL⁻¹, an interface layer having an FcTc₂ concentration of 1.0 mg mL⁻¹, and an interface layer having an FcTc₂ concentration of 2.0 mg mL⁻¹. These results indicate reduced levels of non-radiative recombination for the device comprising the interface layer 108, possibly due to a reduction in perovskite surface defects.

TABLE 1

| | τ₁ (ns) | τ₂ (ns) | τ_{avg} (ns) |
|---|---|---|---|
| Comparative Solar | 98.11 | 1173.63 | 1166.74 |
| Cell 1 | | | |
| Solar Cell Example | 440.22 | 2187.88 | 2159.22 |
| 1 | | | |

Table 2 shows the photovoltaic parameters of best performing PSCs modified with the different concentrations of Fc₂Tc₂.

TABLE 2

| Concen. (mg | | | | |
|---|---|---|---|---|
| mL⁻¹) | V_{OC} (V) | J_{SC} (mA cm⁻²) | FF | PCE (%) |
| 0.5 | 1.165 | 25.42 | 83.48 | 24.72 |
| 1 | 1.191 | 25.47 | 83.82 | 25.43 |
| 2.0 | 1.160 | 25.11 | 79.92 | 23.28 |

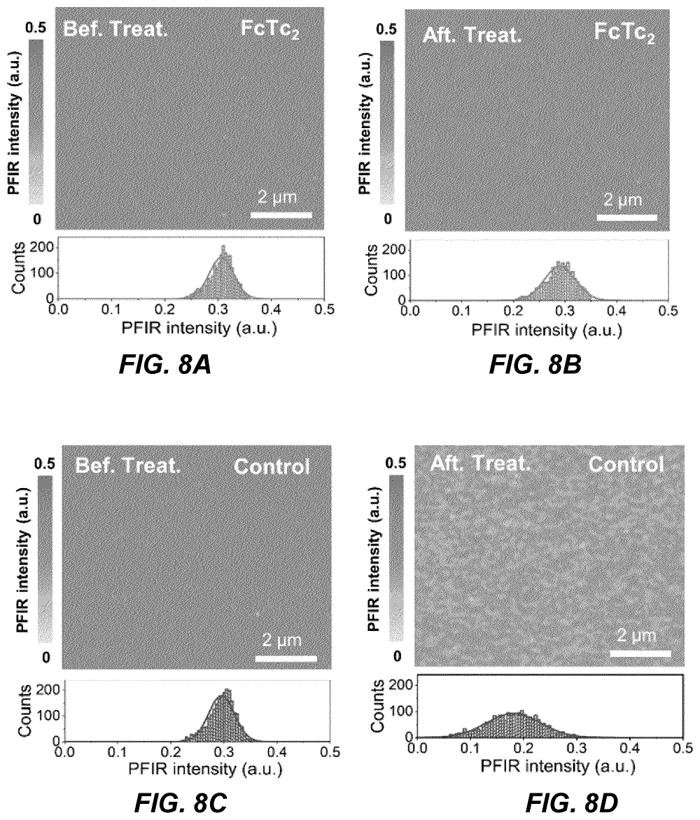

In triple-cation mixed-halide perovskite, the chemically reactive components such as MA⁺ and I⁻ at the perovskite layer 110 surface can volatilize and migrate via photo/thermal effect, resulting in photovoltaic performance degradation. To estimate the effect of FcTc₂ on perovskite stability, the MA⁺ cation of the control and FcTc₂-functionalized perovskite films was probed by peak force infrared (PFIR) microscopy under illumination and heat conditions. The PFIR mapping shows that the intensity and distribution of MA⁺ cations in Solar Cell Example 1 are well maintained after aging for 1000 hours (see FIGS. 8A and 8B), whereas the Comparative Solar Cell 1 exhibits significant reduction of intensity and broadening of distribution of the MA signal (FIGS. 8C and 8D). These results suggest ion migration and volatilization are more prone to occur in the absence of the interface layer, resulting in increased surface defects, thus affecting the operating stability of perovskite devices. However, FcTc₂ can anchor surface ions and reduce migration, producing a more uniform and stable surface component distribution.

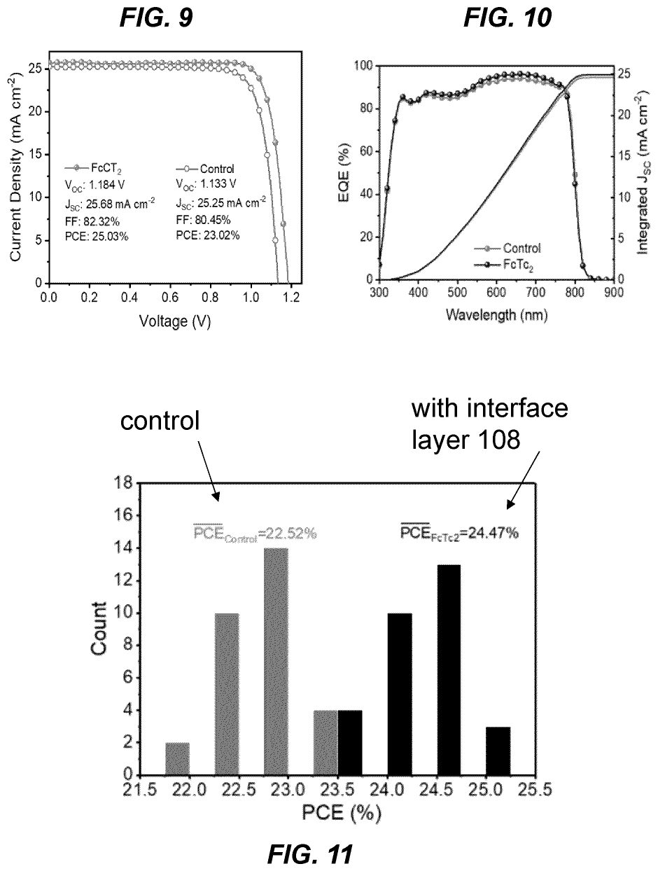

FIG. 9 shows the current density-voltage (J-V) curves of devices for Solar Cell Example 1 and Comparative Solar Cell 1 under AM 1.5 G simulated solar illumination, in which the concentration of FcTc₂ was optimized to be 1.0 mg mL⁻¹ to obtain the best performance (see the comparative experimental results below in Table 3).

TABLE 3

| | | J_{SC} | | |
|---|---|---|---|---|
| | V_{OC} (V) | (mA cm⁻²) | FF (%) | PCE (%) |
| Control | 1.130 ± 0.011 | 24.95 ± 0.40 | 79.89 ± 0.81 | 22.52 ± 0.43 |
| | (1.133) | (25.25) | (80.45) | (23.02) |
| 0.5 mg mL⁻¹ | 1.138 ± 0.011 | 24.93 ± 0.50 | 79.72 ± 1.24 | 22.60 ± 0.50 |
| | (1.143) | (25.33) | (80.48) | (23.31) |
| 1.0 mg mL⁻¹ | 1.178 ± 0.007 | 25.40 ± 0.20 | 81.80 ± 1.09 | 24.48 ± 0.37 |
| | (1.184) | (25.68) | (82.32) | (25.03) |
| 2.0 mg mL⁻¹ | 1.150 ± 0.013 | 25.62 ± 0.28 | 77.03 ± 1.14 | 21.81 ± 0.40 |
| | (1.146) | (24.82) | (78.84) | (22.43) |

As shown in FIG. 9, Comparative Solar Cell 1 exhibited a maximum PCE of 23.02%, with an open-circuit voltage (V_{OC}) of 1.133 V, a short-circuit current density (J_{SC}) of 25.25 mA cm⁻² and a fill factor (FF) of 80.45%. Solar Cell Example 1 exhibited an enhanced PCE of 25.03%, with an increased V_{OC} of 1.184 V, a J_{SC} of 25.68 mA/cm² and an FF of 82.32%. Solar Cell Example 1 also exhibited a low hysteresis. Corresponding external quantum efficiency (EQE) spectra (shown in FIG. 10) yield integrated J_{SC} with a small variation from the values obtained from J-V measurements. Solar Cell Example 1 was also measured at the maximum power point (MPP) to obtain a stabilized photocurrent of 23.70 mA cm-2 and stabilized PCE of 24.17%.

One of the best-performing devices having the structure of Solar Cell Example 1 was validated by an independent solar cell-accredited laboratory (National Institute of Metrology, China) for certification, where a PCE of 24.3% (with V_{OC}=1.179 V, J_{SC}=25.59 mA cm⁻², and FF=80.60%) was confirmed. This is the highest certified efficiency among all inverted PVSCs to date. PCE measurements are also provided in FIG. 11 (under AM 1.5 G simulated solar illumination), which shows a histogram of the PCE values for 30 devices with and without an interface layer. The PCE measurements exhibited good reproducibility, with an average PCE of 22.52% for Comparative Solar Cell 1, and 24.47% for Solar Cell Example 1, respectively.

In addition, quantitative analysis of the photovoltage loss (V_{OC} loss) was conducted for Comparative Solar Cell 1 and Solar Cell Example 1 according to detailed balance theory. An EQEEL of 1.5% for the control device and 7.0% for Solar Cell Example 1 were obtained from electroluminescence (EL) spectra, leading to 108.57 and 68.75 mV of ΔV₃ (V_{OC} loss from the non-radiative recombination), respectively. It is suggested that the FcTc₂ acts as an interfacial modifier to significantly suppress non-radiative recombination. Values of the three components of V_{OC} loss (ΔV₁, ΔV₂, ΔV₃) were calculated in accordance with Appendix 1, and the calculated values are summarized in Table 4. A V_{OC} loss of 363 mV is one of the lowest values amongst inverted PVSCs.

TABLE 4

| | E_{g, PV} | V_{OC, SQ} | V_{OC} | ΔV₁ | ΔV₂ | ΔV₃ | V_{OC, loss} | V_{OC}* |
|---|---|---|---|---|---|---|---|---|
| Device | (eV) | (V) | (V) | (mV) | (mV) | (mV) | (mV) | (V) |
| Comparative | 1.548 | 1.276 | 1.133 | 274.07 | 31.50 | 108.57 | 414.14 | 1.134 |
| Solar Cell 1 | | | | | | | | |
| Solar Cell | 1.548 | 1.276 | 1.184 | 273.63 | 20.67 | 68.75 | 363.05 | 1.185 |
| Example 1 | | | | | | | | |

V_{OC} is the value extracted from J-V curve
V_{OC}* is the value based on the E_{g, PV} and V_{OC, loss}

FIG. 25 shows the electrostatic potential distribution of the different Fc compounds via density functional theory (DFT) simulation. The oxygen atoms in the carboxylate end groups on each functionalized Fc compound exhibit the strongest negative electrostatic potential, which can preferentially interact with the cations in the perovskite structures. Moreover, the electrostatic potentials at the carboxylate units for FcTc₂, Fc₂Tc₂ and Fc₃Tc₂ are −29.79, −29.17 and −30.50 kcal mol⁻¹, respectively. The difference in electrostatic potentials is related to the conformation of the molecule, and the relatively small electrostatic potential value for Fc₂Tc₂ at the carboxylate unit may be due to its most balanced molecular conformation. Although the various Fc unit numbers slightly affect the electrostatic intensity of the different systems, they do not change the overall electrostatic distribution and the interaction between perovskite and Fc-based compounds.

The interaction between the functionalized Fc compounds and perovskite surface was investigated using X-ray photoelectron spectroscopy (XPS) (FIGS. 25c and d, 31, 32). The binding energies for Pb 4f and I 3d core levels of the Fc-treated perovskite films all shift marginally to higher levels than those of the control film, suggesting an altered electronegativity on the perovskite surface, which demonstrates the interaction between functionalized Fc compounds and uncoordinated sites on the perovskite surface. Additionally, the UV-vis absorption spectra and Atomic force microscopy (AFM) images in FIG. 33, 34 indicate that the interaction has no influence on the optical properties and morphology of the perovskite films.

To understand the effect of the organometallic motif, the valence evolution of Fc through XPS was estimated as shown in FIG. 25e. The Fe 2p orbital spectra demonstrate that the iron centre exists in both the Fe³⁺ and Fe²⁺ states, with binding energies of 710.1 eV for 2p_{3/2} (723 eV for 2p_{1/2}) and 708 eV for 2p_{3/2} (720.5 eV for 2p_{1/2}), respectively. Moreover, as the number of Fc units increases, the ratio of Fe³⁺/Fe²⁺ drops, implying that Fc compounds bound to the surface of the perovskite films have a redox limitation. This change is consistent with previously reported valence alterations for ferrocene or cobaltocene, and may be attributed to the iodide anions released by chemical damage to the perovskite crystal surface acting as counterions to the oxidized Fc cations.

To gain deeper insight into the charge transfer between the functionalized Fc compounds and perovskite, electrostatic force microscopy (EFM) was performed on the perovskite films (FIG. 25f, 25g, 35), which provides direct information on carrier type and concentration.

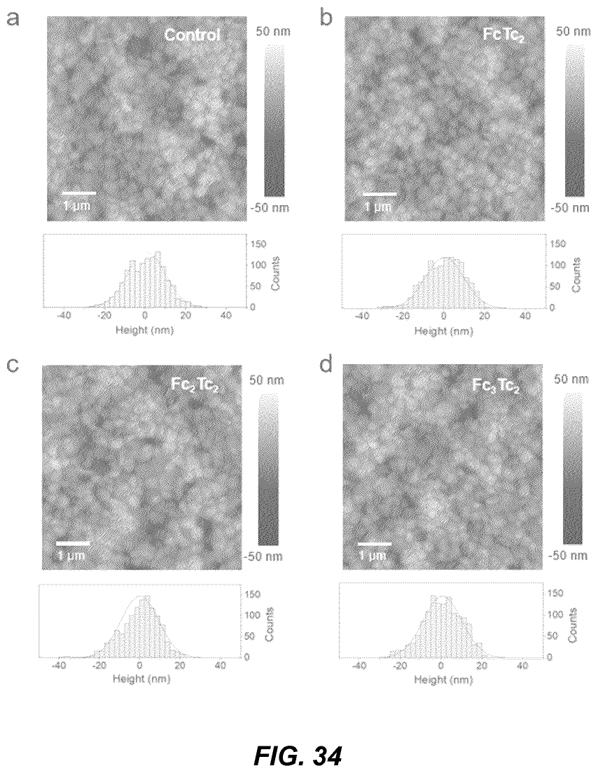

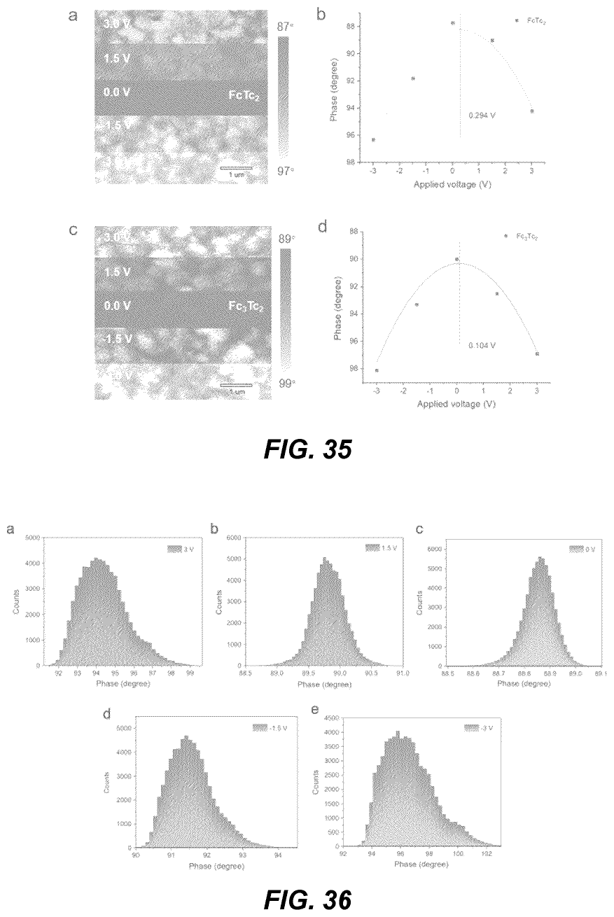

EFM provides a powerful tool to discover direct charge transfer of mixed electron systems. In the test protocol of EFM, a bias voltage (−3 to 3 V with a 1.5 V step) is applied on the tip of the probe to allow extraction of Coulomb forces. FIGS. 1f and 1g show the phase shift mapping of the entire scan area at different bias voltages integrated in one image for comparison. The statistics of phase angle under different bias voltages are shown in FIGS. 34 and 35 by counting the data on FIGS. 1f and 1g. Further, the statistical mean is shown in FIG. 1h with a parabolic fit to it. The negative shift of the fitted parabolic axis of symmetry represents the negative charge induced at a surface point or region.

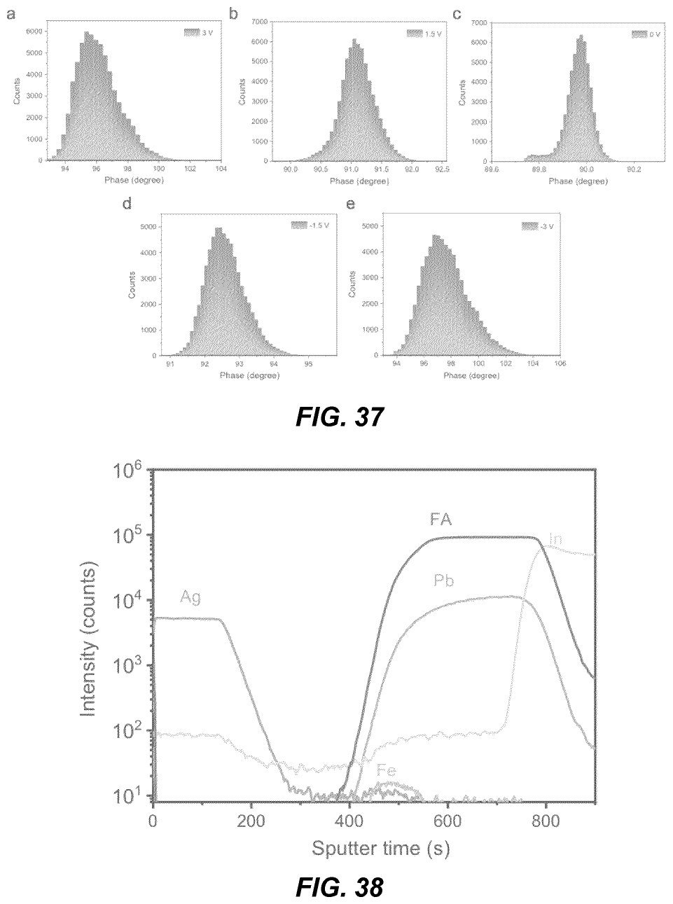

The pristine and Fc₂Tc₂-treated films are representative and displayed in FIGS. 25f and 25g, and show integrated phase shift mappings throughout the whole scan region at various bias voltages (from −3 V to 3 V), with corresponding phase angle statistics shown in FIGS. 36 and 37. Both pristine and Fc-treated perovskite films exhibit easily discernible phase shift degrees. In FIG. 25h, the negative shift of the fitted parabola symmetry axis corresponds to the negative charges produced at the sample surface.³¹ For the Fc-modified perovskite, the number of negative charges rises since some Fc species are already ionized due to their high electron delocalization. This indicates that electrons are transferred from Fc compound to perovskite surface, leading to charge redistribution on perovskite surface.

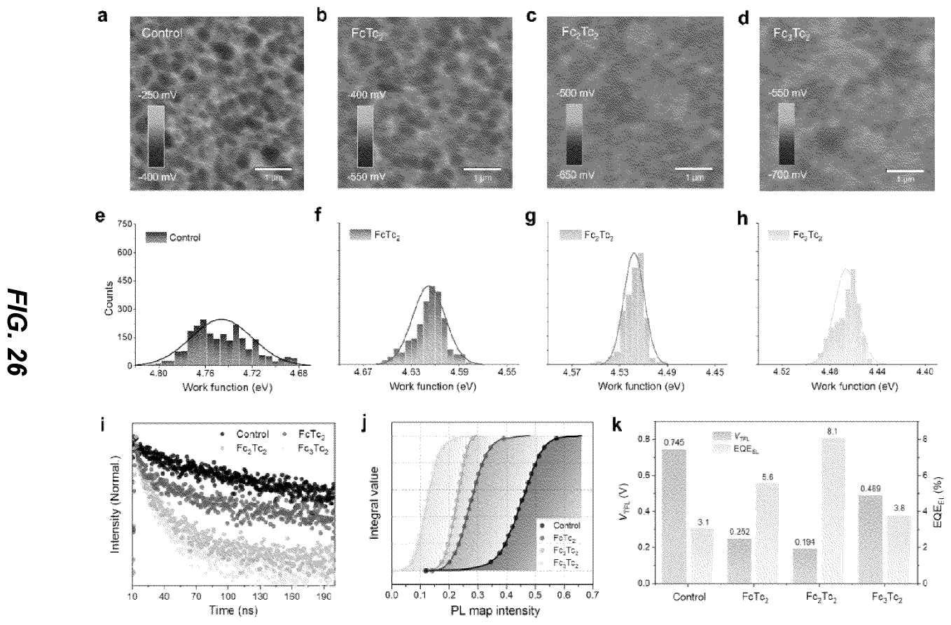

Surface manipulation of the perovskite films can tune the work function and carrier concentration. Kelvin probe force microscopy (KPFM) was applied to determine the surface potential of the perovskite films. The contact potential difference (CPD) images of the pristine and the Fc-treated perovskite films are shown in FIGS. 26a to 26d. The Fc-modified perovskite films exhibit a gradually increasing CPD value compared to the pristine films following an increase of Fc units, which originates from the interface charge transfer. Furthermore, the Fc-modified perovskite films exhibit a steadily growing uniformity of surface potential with the introduction of more Fc units (FIG. 26e). The reduced surface potential difference can not only reduce interfacial nonradiative recombination loss, but also accelerate and homogenize charge extraction efficiency.

In addition, the surface work function of the perovskite films with different Fc compound modifications was determined by calibrating the work function with an Au reference. In FIGS. 26e to 26h, the pristine perovskite film produces a work function of 4.74±0.07 eV. The surface manipulation via Fc compound causes a negative shift of work function, and increasing the number of Fc units results in a more negative shift, leading to a value of 4.46±0.02 eV with a change of around 300 meV for the Fc₃Tc₂-modified perovskite film. Moreover, the changed work function only occurs within the surface layer of perovskite films, since the Fc compounds are only bound to the perovskite surface according to the TOF-SIMS result in FIG. 38.

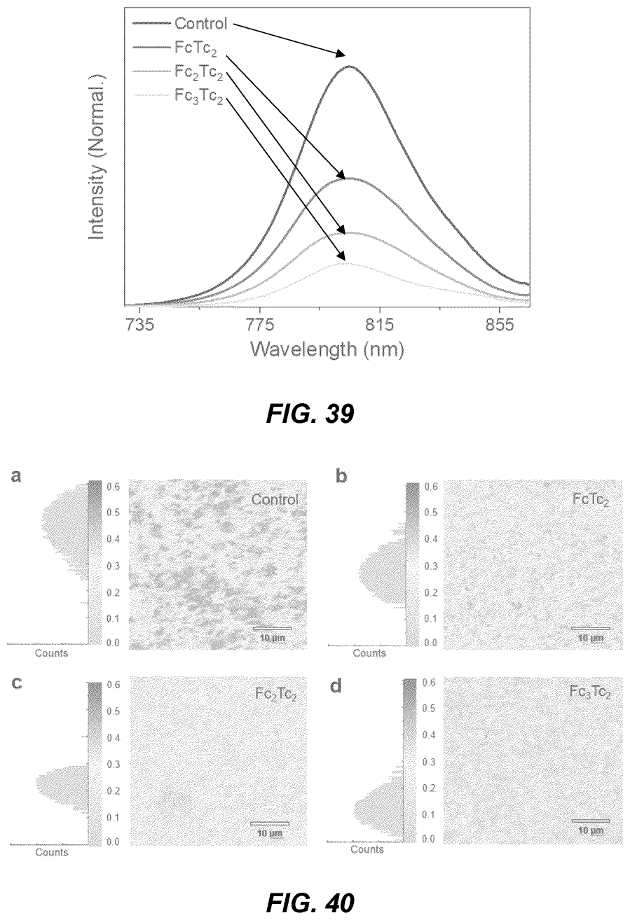

For validating how surface manipulation affects interfacial charge extraction and recombination, steady-state and time-resolved photoluminescence (PL and TRPL) were firstly conducted on perovskite/ETL films (with a structure of glass/perovskite/C₆₀). In FIG. 26i and FIG. 39, the functionalized Fc-treated perovskite films display a significant decline of PL intensity compared to the control one. Moreover, the carrier lifetime via fitting the TRPL spectra decreases from 189.7 ns to 33.5 ns on increasing the number of Fc units. The reduction of PL intensity and lifetime indicates facilitated charge extraction from perovskite to ETL. PL mapping on the perovskite/ETL films was performed (FIG. 40). The PL mapping intensity was counted and the integral value is presented in FIG. 26j, where the x-axis is PL mapping intensity, and the integral area represents PL homogeneity. The control film shows inhomogeneous PL intensity, suggesting an unbalanced charge extraction efficiency. In contrast, the incorporation of Fc compounds and the optimization of Fc unit to Fc₂Tc₂ leads to more uniform PL emission and decreased PL intensity compared to those of the control film, which further proves the carrier extraction is accelerated and homogenized due to the introduction of Fc compounds.

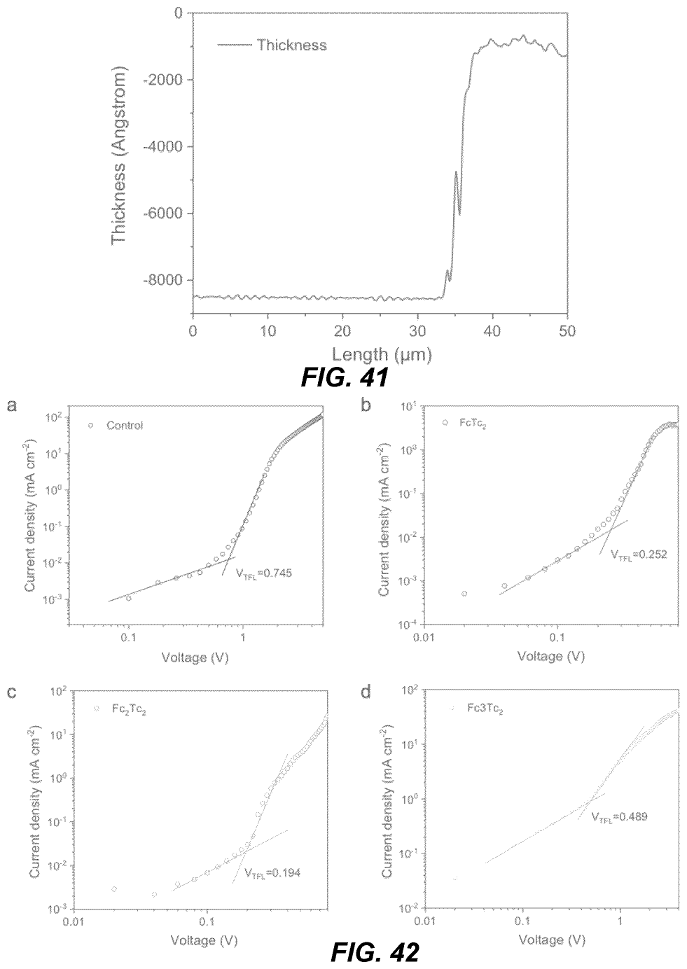

In addition to charge extraction, carrier recombination and interfacial defect states have also been investigated. The space-charge-limited-current (SCLC) technique was first carried out (FIGS. 41 and 42) on the electron-only device to determine the trap density (Nₜ) according to the trap-filling voltage V_{TFL}=eNₜL²/2εεₒ.

The electron-only devices with the FTO/TiO₂/perovskite/Fc/C60/BCP/Ag structure were prepared to calculate the defect density (N). In the SCLC regime, the current is dominated by charge carriers injected from the contacts and the current-voltage characteristics become quadratic (I˜V²). FIG. 38 shows the J-V curves of the fabricated devices on a double logarithmic scale, which comprises the Ohmic region, the trap-filling limit (TFL) region and the Child region. In the TFL region, the trap-state density (Nₜ) can be calculated by the following equation:

$${N}_{t} = \frac{2 {εε}_{0} {V}_{TFL}}{{qL}^{2}} \qquad ( S1 )$$

where ε and εₒ are the relative dielectric constant and vacuum permittivity, respectively. V_{TFL} is the onset voltage of TFL region, q is elementary charge. L represents perovskite thin film thickness.

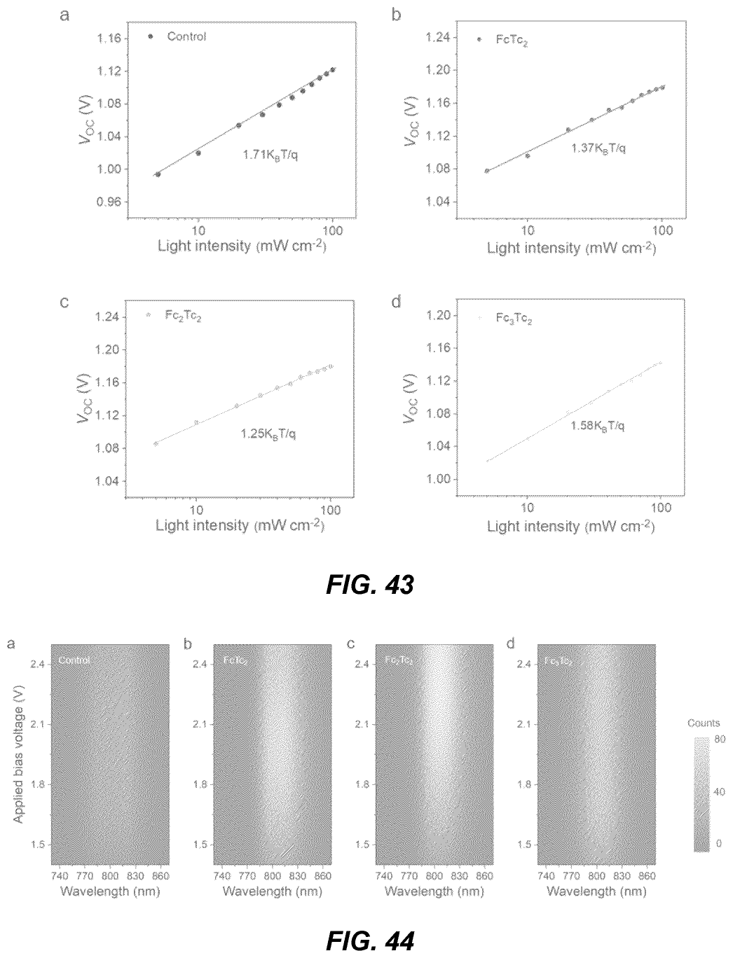

In FIG. 26k, after functionalization by the Fc compounds, the trap-filling voltage decreases gradually from 0.745 V (control device) to 0.194 V (Fc₂Tc₂-modified device) but increases to 0.489 V for the Fc Tc₂ analogue. A similar trend can also be observed in the variation of ideality factor (n) in FIG. 43,³⁴ which reduces from 1.71 to 1.25 after introducing the Fc₂Tc₂ but increases to 1.58 when using Fc Tc₂ for surface modification. These findings demonstrate that the incorporation of functionalized Fc molecules can efficiently suppress interfacial defects and carrier recombination; however, this effect is diminished when excess Fc units are included.

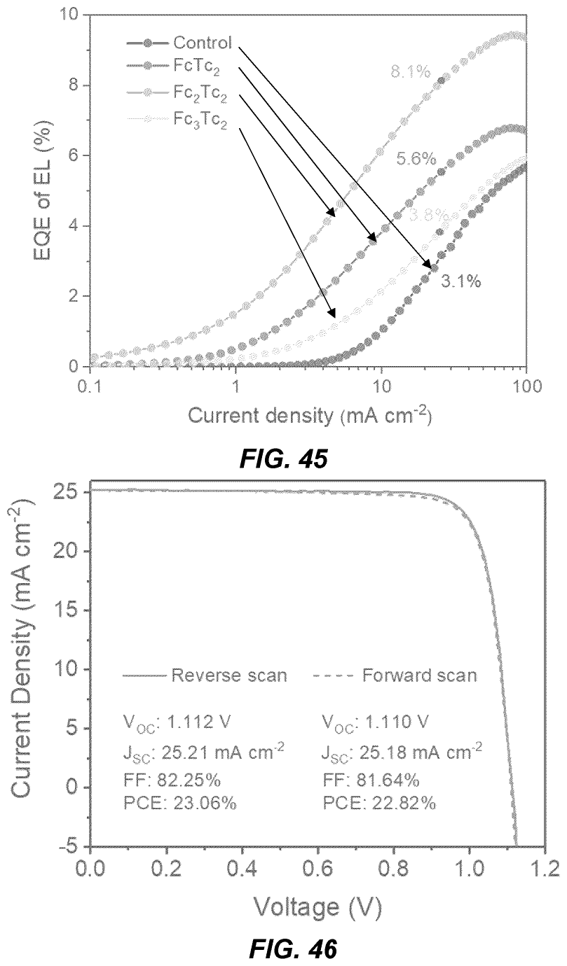

Electroluminescence (EL) measurements in the dark were performed under forward voltage bias (FIGS. 44 and 45). The films treated with Fc₂Tc₂ exhibit more predominant emission intensity and narrower emission range compared to the control, which further confirms the reduced non-radiative recombination loss.³⁵ Moreover, it is encouraging that, in FIG. 26k, the Fc₂Tc₂-modified device demonstrates an 8.1% EQE_{EL} efficiency, which is the highest value among all inverted perovskite photovoltaic devices to date. In comparison, the control device only shows 3.1% EQE_{EL} efficiency under the same conditions.

To investigate the effects of surface modification on PV performance, inverted PV devices were fabricated with a configuration of indium tin oxide (ITO)/poly[bis(4-phenyl)(2,4,6-trimethylphenyl) amine] (PTAA)/perovskite/Fc molecules/C60/2,9-dimethyl-4,7-diphenyl-1,10 phenanthroline (BCP)/silver (Ag) (FIGS. 27a and 27b). FIGS. 27c and 27d show the current-voltage (J-V) curves and the efficiencies of the PSCs with the different Fc compounds. The control device exhibits a maximum PCE of 23.06%, with an open-circuit voltage (V_{OC}) of 1.112 V, a short-circuit current density (J_{SC}) of 25.21 mA cm⁻², and a fill factor (FF) of 82.25%. After introducing the Fc compounds, the PSCs exhibit considerably increased V_{OC} and FF (Table 5).

TABLE 5
Photovoltaic parameters of best-performing PSCs
modified with different functional Fc molecules.

| | V_{OC} (V) | J_{SC} (mA cm⁻²) | FF (%) | PCE (%) |
|---|---|---|---|---|
| Control | 1.112 | 25.21 | 82.25 | 23.06 |
| FcTc₂ | 1.184 | 25.39 | 83.26 | 25.03 |
| Fc₂Tc₂ | 1.191 | 25.47 | 83.82 | 25.43 |
| Fc₃Tc₂ | 1.159 | 25.29 | 82.93 | 24.31 |

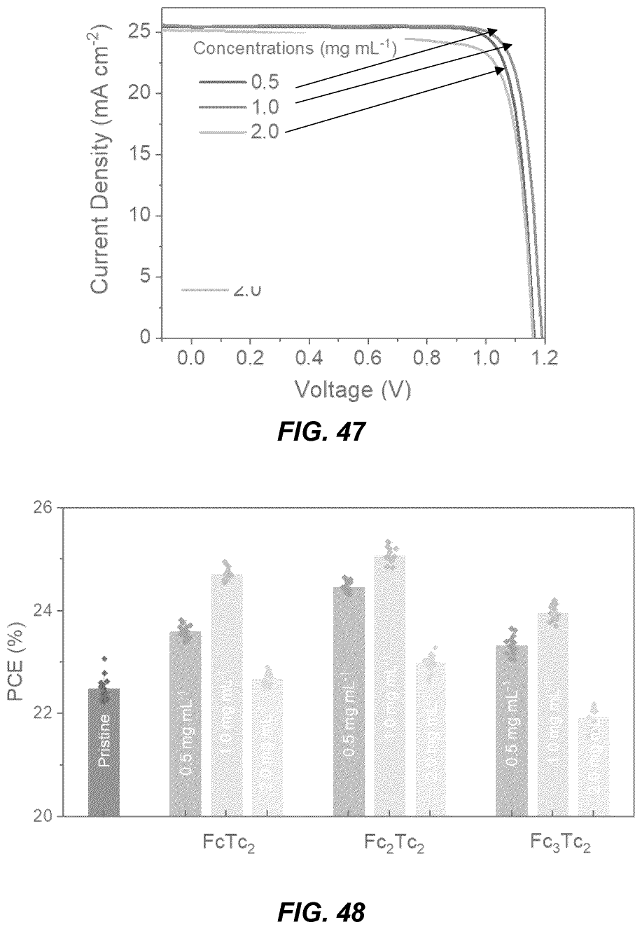

The Fc₂Tc₂-treated device produces a headline efficiency of 25.43%, with a V_{OC} of 1.191 V, J_{SC} of 25.47 mA cm⁻², FF of 83.82%, and a negligible hysteresis compared to the control device (FIG. 27e and FIG. 46). The PV performance with varied concentration of Fc compounds is summarized in FIGS. 47 and 48.

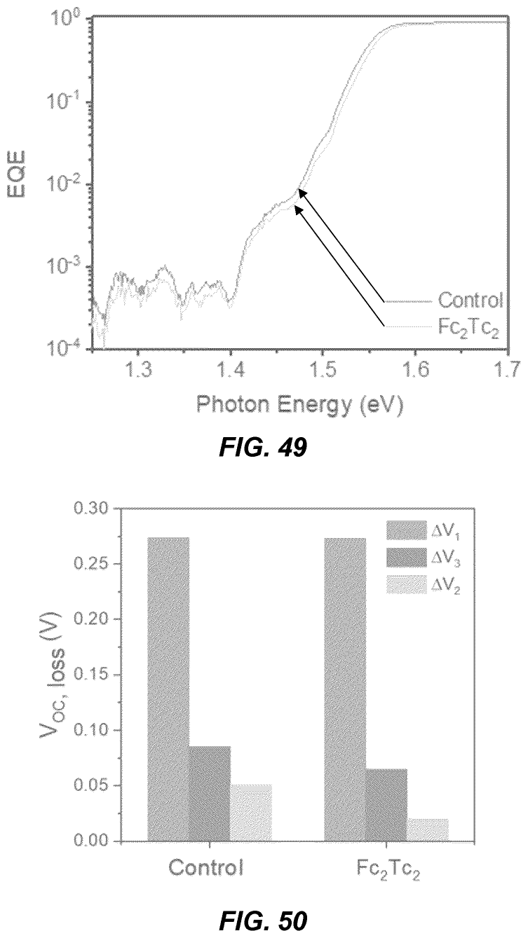

The external quantum efficiency (EQE) spectra (FIG. 27f) yielded integrated J_{SC} values that deviated only marginally from the J-V measurements. The stabilized efficiency of the Fc₂Tc₂-modified device was also evaluated at the maximum power point (MPP), producing a stable photocurrent of 24.25 mA cm² and a stabilized PCE of 25.22% (FIG. 27g). Moreover, the devices also exhibited very good reproducibility and only a small deviation value for each PV parameter, with an average PCE of ˜22.6% for the control device and ˜25.0% for the Fc₂Tc₂-modified device (FIG. 27h). Additionally, the energy loss analysis shows non-radiative recombination losses of 85.94 mV and 64.97 mV for the control and Fc₂Tc₂-modified devices (FIGS. 49 and 50, Table 6), respectively, further confirming the remarkable contribution of Fc₂Tc₂ to the improvement in performance of PSCs.

TABLE 6
Key parameters of energy loss in PSCs with and without Fc₂Tc₂

| | E_{g, PV} | V_{OC, SQ} | V_{OC} | ΔV₁ | ΔV₂ | ΔV₃ | V_{OC, loss} | V_{OC}* |
|---|---|---|---|---|---|---|---|---|
| Device | (eV) | (V) | (V) | (mV) | (mV) | (mV) | (mV) | (V) |
| Control | 1.55 | 1.28 | 1.11 | 274.05 | 51.64 | 85.94 | 411.62 | 1.13 |
| Fc₂Tc₂ | 1.55 | 1.28 | 1.18 | 273.63 | 20.96 | 64.97 | 359.57 | 1.19 |

V_{OC} is the value extracted from J-V curve
V_{OC}* is the value based on the E_{g, PV} and V_{OC, loss}

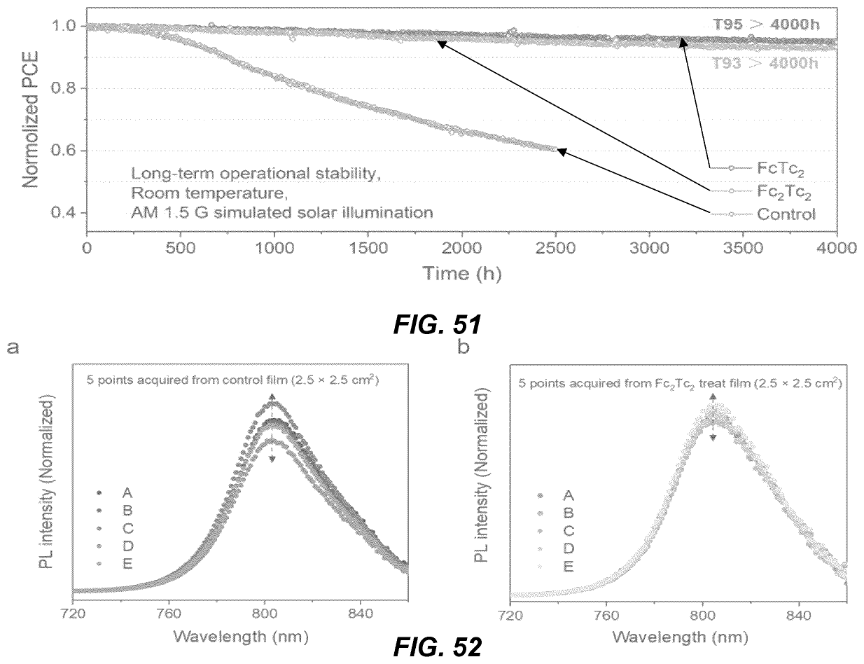

The long-term operating stability of the encapsulated devices at MPP under continuous one sun illumination under a N₂ atmosphere was examined. The Fc₂Tc₂-modified device demonstrates outstanding stability with over 93% PCE (>τ₉₃) after 4000 hours (FIG. 51) compared with the control device, which lost more than 60% of its initial PCE after 2500 hours. The results showed a comparable operational stability with the FcTc2-based device (FIG. 51).

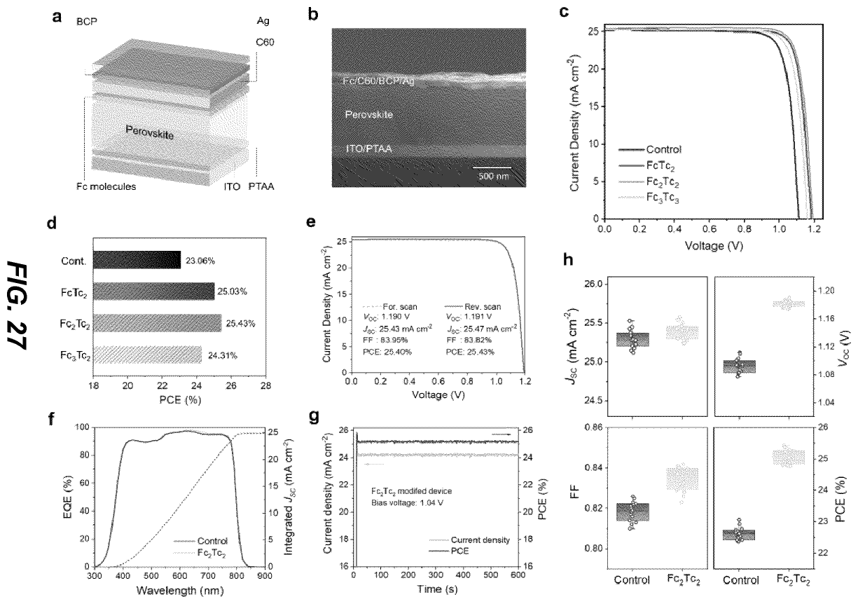

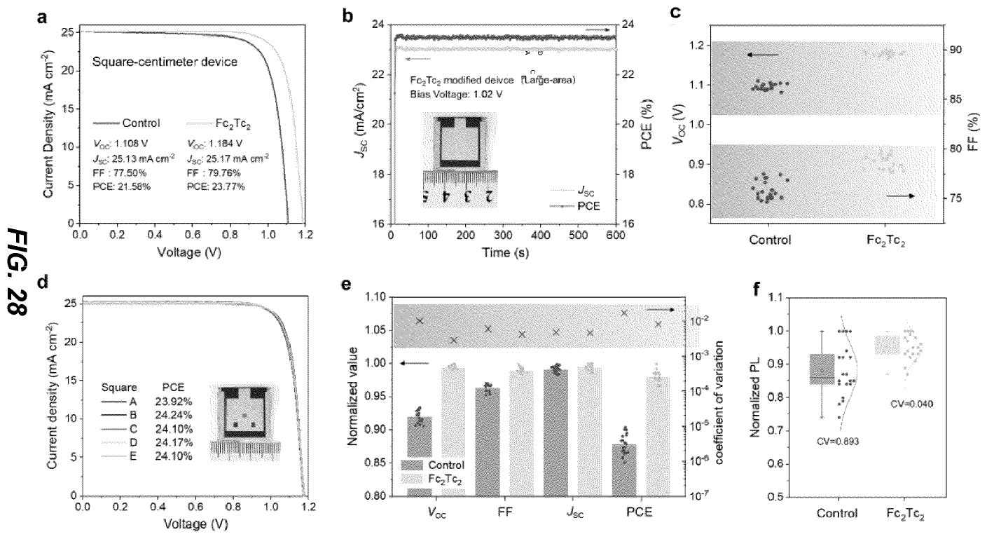

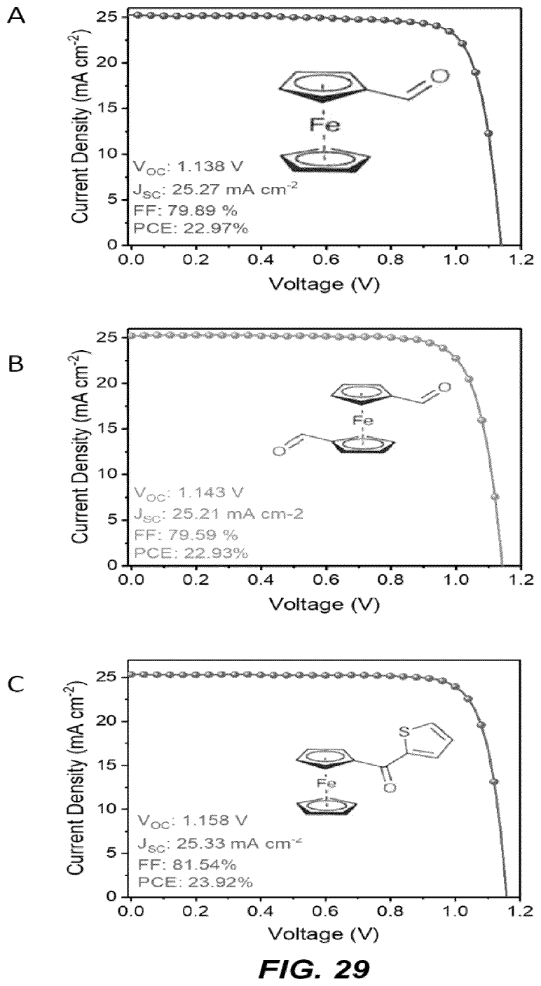

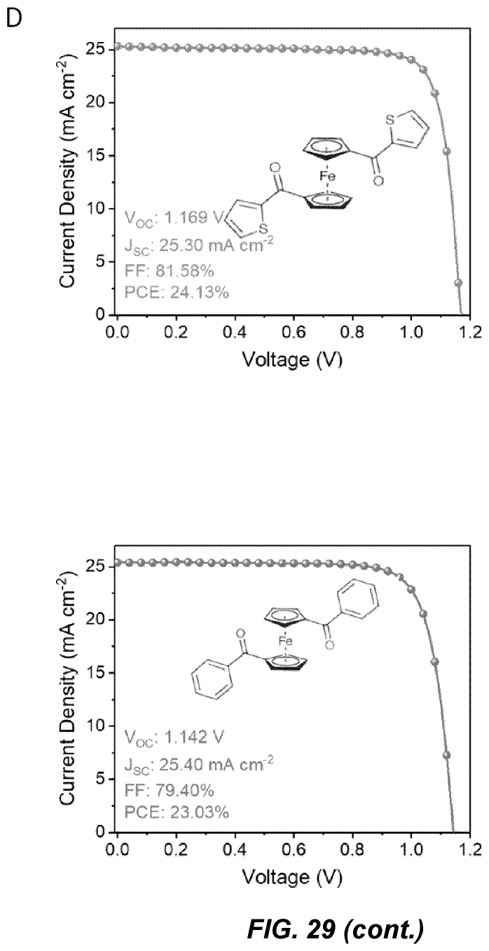

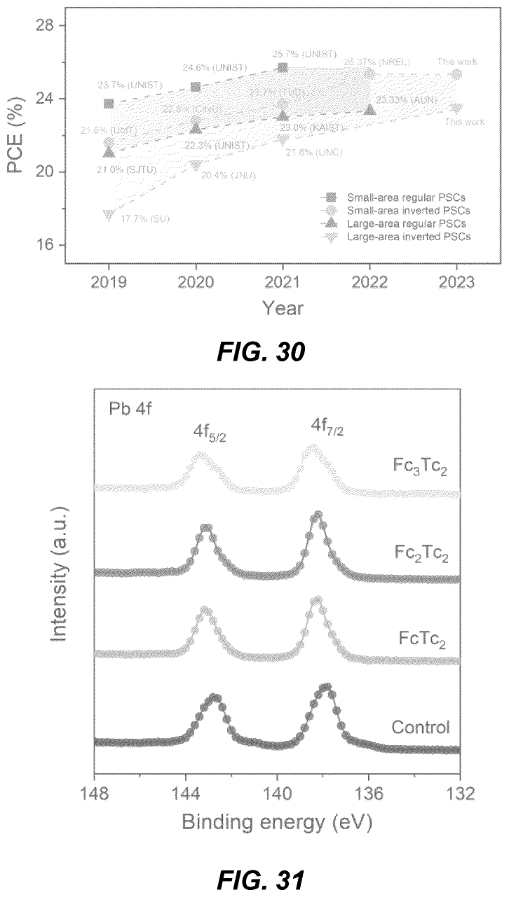

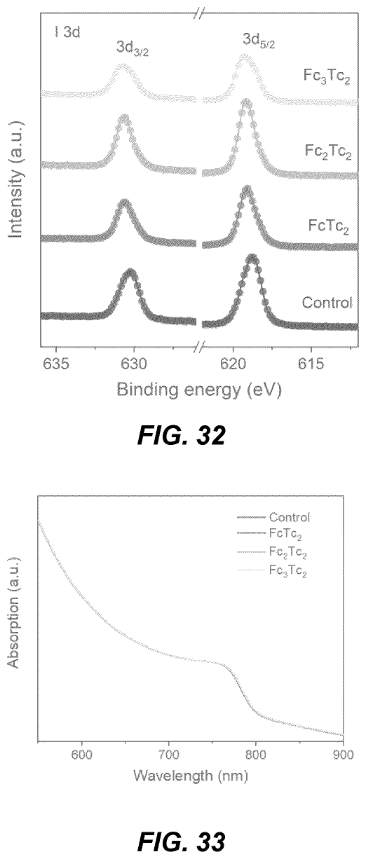

After determining the outstanding small-area PV performance achieved by Fc₂Tc₂ modification, the inventors further fabricated large-area cells (with an active area of 1.008 cm²) and estimated their performance. FIG. 28a shows the J-V curves of the best performing large-area PSCs with and without Fc₂Tc₂. The control device produces a PCE of 21.58%, with a J_{SC} of 25.13 mA cm⁻², a V_{OC}=1.108 V, and a FF of 77.50%. In contrast, the Fc₂Tc₂-modified device exhibited a significant improvement in FF (79.76%) and V_{OC} (1.184 V), ultimately achieving a headline efficiency of 23.77%.

Furthermore, in FIG. 28b, the Fc₂Tc₂-modified device displayed a stable photocurrent output of 23.05 mA cm⁻² and a stabilized PCE of 23.51% under a bias voltage of 1.02 V. FIG. 28c shows a statistical distribution of V_{OC} and FF for 20 pristine and target devices. Both V_{OC} and FF for the modified devices are higher than those for control devices, which is consistent with the results of small-area devices in FIG. 28h, suggesting that the improved performance of large-area devices also originates from accelerated interfacial charge transfer and suppressed non-radiative recombination.

For further assessing the PV performance homogeneity of large-area device, the inventors recorded J-V curves of our devices at five separate places i.e. positioned in the centre and four corners of the device active region (FIG. 28d). All the PV metrics of Fc₂Tc₂-based device, collected from the J-V curves in these five areas using a mask with a square aperture area of 0.0414 cm², exhibited very little variation (Table 7).

TABLE 7
Small-area photovoltaic parameters captured
at different locations of the 1 cm² device.

| Position | V_{OC} (V) | J_{SC} (mA cm⁻²) | FF (%) | PCE (%) |
|---|---|---|---|---|
| 1 | 1.172 | 25.27 | 80.78 | 23.92 |
| 2 | 1.177 | 25.02 | 82.33 | 24.24 |
| 3 | 1.177 | 25.24 | 81.11 | 24.10 |
| 4 | 1.175 | 25.21 | 81.60 | 24.17 |
| 5 | 1.173 | 25.04 | 82.06 | 24.10 |

More significantly, in FIG. 28e, the Fc₂Tc₂-modified device exhibits greater FF and V_{OC} values, as well as lower coefficients of variation (CV) than the control devices, according to the statistics of small-area PV metrics captured in the large-area devices. These results indicate that the PV performance reaches optimal value across the square-centimeter scale after Fc₂Tc₂ modification.

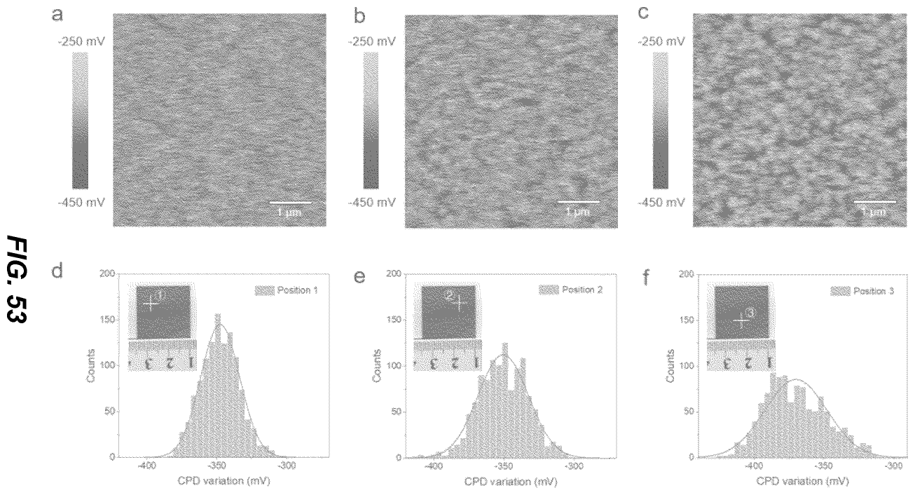

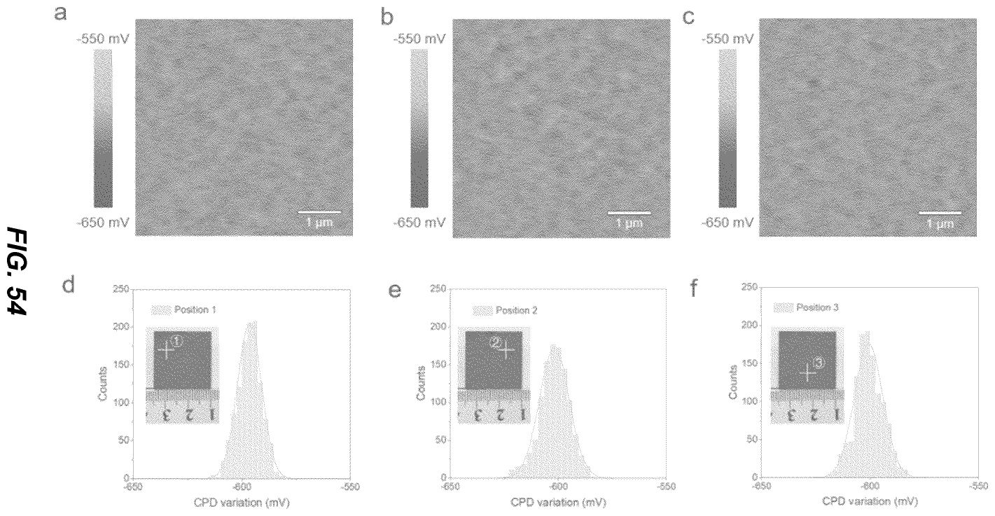

To identify the reasons for improved PV performance and homogeneity, steady-state PL measurement was conducted on five distinct regions of perovskite/ETL films (FIG. 28f). The Fc₂Tc₂-treated samples exhibit more consistent PL intensity compared to the control ones as shown in FIG. 52. The number of collected samples was expanded and normalized based on the highest PL intensity in each film. As shown in FIG. 28f, the CV value of the modified film is 0.040, lower than that of the control one (0.893), which indicates more uniform carrier extraction and transfer on the square centimeter scale. Additionally, KPFM characterization was applied to evaluate the surface potential variation of different regions in perovskite films. In FIGS. 53 and 54, modification via Fc₂Tc₂ leads to more uniform surface potential at each independent region. Although the potentials at different locations deviate slightly for both control and target films, the Fc compound can reduce potential difference for each localized location, which allows for the optimal carrier extraction efficiency across a wide range of large-area perovskite devices, therefore, enabling scalable PSCs to achieve performance optimization in different places.

### Stability

To investigate the effect of FcTc₂ functionalization on device stability, the efficiency evolution under various conditions was monitored.

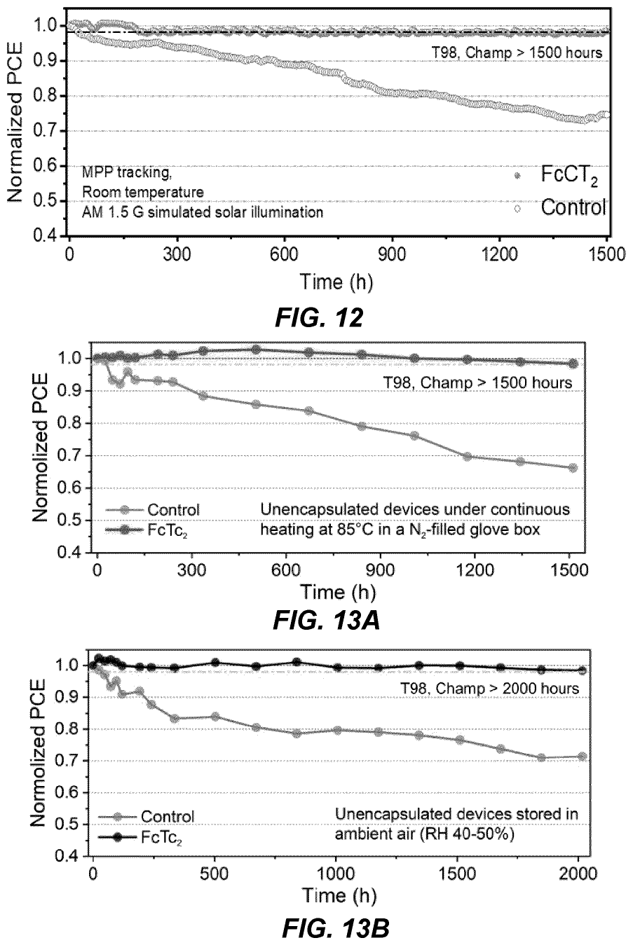

Firstly, the operational stability of unencapsulated devices was examined via maximum power point (MPP) tracking under continuous one-sun illumination under N₂ atmosphere. As shown in FIG. 12, Solar Cell Example 1 retained its initial efficiency in the first 200 hours and merely exhibited a decay of less than 2% over 1500 hours. In comparison, Comparative Solar Cell 1 decreased to 72% of its initial efficiency.

The stability of unencapsulated devices was further measured under heat (FIG. 13A) and ambient (FIG. 13B) conditions, respectively. It can be seen that in both instances the performance of the Comparative Solar Cells 1 dropped significantly to below 80% of the initial efficiency over 800 hours. In contrast, the Solar Cell Example 1 devices showed T98 (time to 98% of initial efficiency) of 2000 hours under an ambient environment, and 1500 hours under continuous heating, respectively. Without wishing to be bound by any theory, as the chemically reactive components (such as MA⁺ and I⁻) at the perovskite surface can readily volatilize and migrate via the photo-, humidity- and thermal-degradation, FcTc₂ may enhance stability through the formation of additional bonding with perovskite surface ions and blocking off any mobile ions from migration.

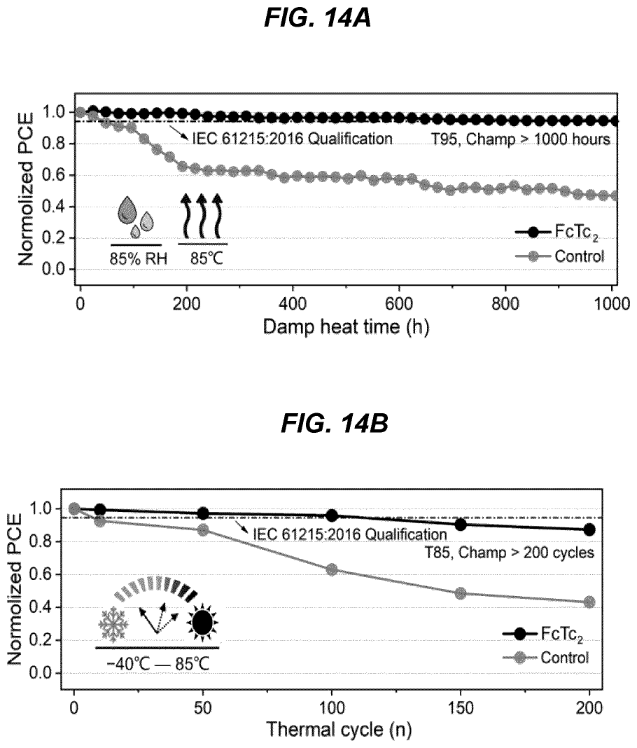

Additionally, strict stability measurements were conducted following the IEC61215:2016 standard, which is the most used international standard for mature photovoltaic technologies. As shown in FIG. 14A, the Solar Cell Example 1 devices exhibited τ₉₅ of over 1000 hours under the damp heat test (85° C./85% RH), and thus successfully passed the main point of IEC61215:2016 qualification for damp and heat conditions. Moreover, as shown in FIG. 14B, under the cycle shocks of cold (−40° C.) and heat (85° C.), over 85% efficiency was retained after 200 cycles for the Solar Cell Example 1 devices; this significantly outperformed the Comparative Solar Cell 1 (40% efficiency retained after 200 cycles). Taken together, these data indicate that FcTc₂-functionalized PVSC devices exhibit very promising efficiency and stability. A perovskite solar cell with such a functional interface layer has the potential for commercialization and to rival silicon solar cells.

### Solar Cell Example 2

MAPbI₃ based devices were fabricated as follows:
The procedures of ITO/Glass substrates cleaning, and hole-transporting layer (PTAA) deposit are consistent with the CS_{0.05}(FA_{0.98}MA_{0.02})_{0.95}Pb(I_{0.95}Br_{0.02})₃ based device fabrication discussed above for Solar Cell Example 1.
The MAPbI₃ precursor solution was prepared by mixing 1.55 M MAI, and 1.63 M PbI₂ in 1 mL DMF:DMSO (5:1/v:v) mixed solvent, and stirring for 2 h before use.
60 μL perovskite solutions were spin-coated onto glass/ITO/HTL at 2000 rpm for 10 s, subsequently at 6000 rpm for 30 seconds.
250 μL CB was slowly dripped onto the centre of the film at 7 seconds before the end of spin-coating. The as-prepared perovskite films were subsequently annealed on a hotplate at 100° C. for 30 min.
The procedures of the FcTc₂ interface layer deposition and the metal electrode evaporation are as described for Solar Cell Example 1.

### Solar Cell Example 3

FAPbI₃ based devices were fabricated as follows:
The procedures of ITO/Glass substrates cleaning, and hole-transporting layer (PTAA) deposit are as for Solar Cell Example 1.
The FAPbI₃ precursor solution was prepared by mixing 2 M FAI, and 2.06 M PbI₂ in 1 mL DMF:DMSO (8:1/v:v) mixed solvent. Then 35 mol % of MACI was added to the perovskite precursor solution and stirred for 2 hours.
60 μL perovskite solutions were spin-coated onto glass/ITO/HTL at 6000 rpm for 40 seconds.
250 μL CB was slowly dripped onto the centre of film at 25 seconds before the end of spin-coating. The as-prepared perovskite films were subsequently annealed on a hotplate at 135° C. for 1 hour.
The procedures of the FcTc₂ interface layer deposition and the metal electrode evaporation are as described for Solar Cell Example 1.

### Solar Cell Example 4

CS_{0.05}(FA_{0.85}MA_{0.15})_{0.95}Pb(I_{0.85}Br_{0.15})₃ based devices were fabricated as follows:
The procedures of ITO/Glass substrates cleaning, and hole-transporting layer (PTAA) deposit are as described for Device Example 1.
The 1.5 M perovskite precursor solution was prepared by mixing CsI, FAI, MABr, PbI₂ (10 mol % excess relative to FAI) and PbBr₂ in 1 mL DMF:DMSO (5:1/v:v) mixed solvent with a chemical formula of CS_{0.05}(FA_{0.85}MA_{0.15})_{0.95}Pb(I_{0.85}Br_{0.15})₃.
60 μL perovskite solutions were spin-coated onto glass/ITO/HTL at 5000 rpm for 30 seconds. 250 μL CB was slowly dripped onto the centre of film at 7 seconds before the end of spin-coating. The as-prepared perovskite films were subsequently annealed on a hotplate at 100° C. for 30 minutes.
The procedures of the FcTc₂ interface layer deposition and the metal electrode evaporation are as described for Device Example 1.

### Comparative Solar Cells 2-4

Comparative Solar Cells 2-4 were prepared as described for Solar Cell Examples 2-4, respectively, except that the FcTc2 layer was omitted.

Table 8 illustrates an increased PCE for each of Comparative Devices 2-4 upon inclusion of the FcTc₂ interface layer.

TABLE 8

| | | | J_{SC} | | |
|---|---|---|---|---|---|
| | V_{OC} | | (mA | PCE | Average |
| Device | (V) | FF (%) | cm⁻²) | (%) | PCE (%) |
| Device 2 | 1.058 | 80.12 | 23.08 | 19.56 | 18.08 |
| Comparative Device 2 | 1.137 | 80.80 | 23.26 | 21.37 | 20.60 |
| Device 3 | 1.033 | 79.40 | 25.36 | 20.80 | 20.08 |
| Comparative Device 3 | 1.095 | 81.23 | 25.38 | 22.57 | 21.42 |
| Device 4 | 1.091 | 82.00 | 22.61 | 20.23 | 19.58 |
| Comparative Device 4 | 1.176 | 81.37 | 22.76 | 21.78 | 20.99 |

The benefits of the interfacial can be seen further with reference to FIGS. 15, 16 and 17, which compare the performance of different perovskite compositions with and without a FcTc₂ interfacial layer.

FIG. 15A illustrates J-V curves of the best performing PVSCs of Solar Cell Example 2, and FIG. 15B illustrates histograms of the measured PCE values for 20 Solar Cell Example 2 devices.

FIG. 16A illustrates J-V curves of the best performing Solar Cell Example 4 device, and FIG. 16B illustrates histograms of the measured PCE values for 20 Solar Cell Example 2 devices.

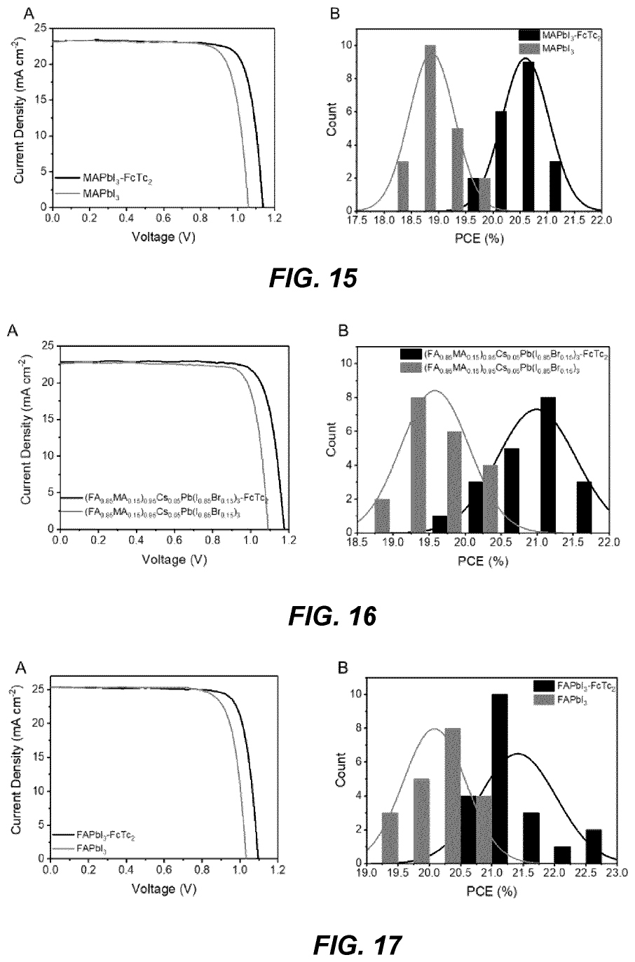

FIG. 17A illustrates J-V curves of the best performing Solar Cell Example 3 device, and FIG. 17B illustrates histograms of the measured PCE values for 20 Solar Cell Example 3 devices.

### Solar Cell Example 5

An “electron-only” solar cell device was fabricated, with a structure of: glass substrate (102)/FTO+TiO₂ (contact 114)/Perovskite layer (110)/interface layer FcTc₂ (108)/C60 (ETL 106)/BCP/Ag contact 104 (as per the inverted structure shown in FIG. 1B and FIG. 3, omitting hole transport layer 112, and replacing ITO with FTO+TiO₂).

### Comparative Solar Cell 5

Comparative Solar Cell 5 was prepared as described for Solar Cell Example 5 but with omission of the FcTc₂ interface layer.

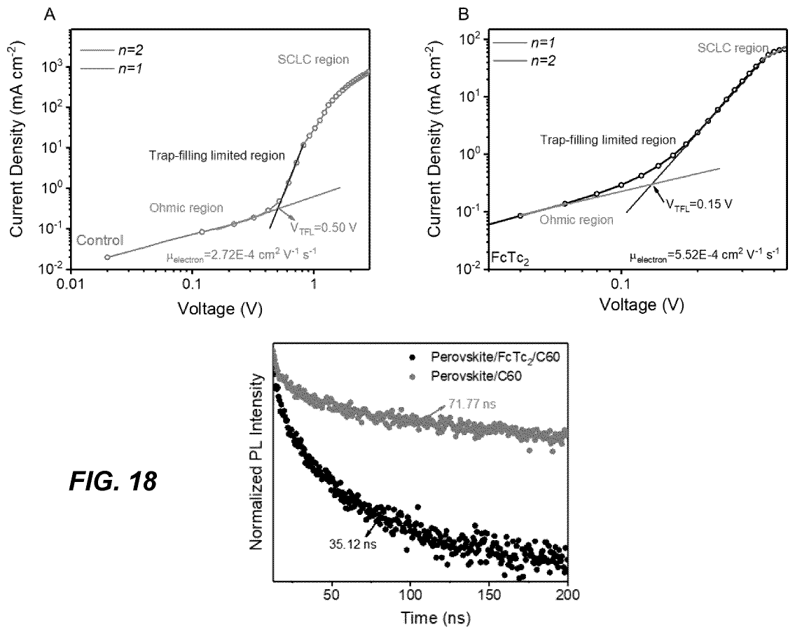

FIGS. 18A and 18B shows space charge limited current (SCLC) measurements of Solar Cell Example 5 and Comparative Solar Cell 5, respectively. It can be seen that the current density increases more after the trap-filled limited voltage (V_{TFL}) has been reached when the interface layer 108 of Solar Cell Example 5 is present as compared to Comparative Solar Cell 5.

The trap-filled limited voltage can be applied to calculate the trap density by the equation of Nₜ=2εε₀V_{TFL}/eL², in which e is the elementary charge, ε is the relative dielectric constant of perovskite, εₒ is the vacuum permittivity, L denotes the thickness of perovskite layer, and Nₜ is the trap density of the perovskite film.

The calculated trap densities are 2.76×10¹⁵ and 8.27×10¹⁴ for the Comparative Solar Cell 5 and Solar Cell Example 5, respectively, indicating that presence of the FcTc₂-modified perovskite film reduces levels of trap density.

As shown in FIGS. 18A and 18B, carrier mobility in the “electron-only” device is enhanced from 2.72×10-4 cm² V⁻¹ s⁻¹ for the Comparative Solar Cell 5 to 5.52×10⁻⁴ cm² V⁻¹ s⁻¹ for the FcTc₂-modified Solar Cell Example 5, according to the SCLC measurements. Assuming that all layers in the Comparative Solar Cell 5 and Solar Cell Example 5 are identical, other than the interface layer, this enhanced carrier mobility can be attributed to faster electron transfer induced by the FcTc₂-modified interface.

As shown in FIG. 18C, carrier lifetime at the perovskite/ETL interface of Solar Cell Example 5 is shorter than that of pristine perovskite/ETL interface of Comparative Solar Cell 5, further indicating that electron extraction is accelerated via FcTc₂.

Since similar improvements in interface carrier transport and extraction were not demonstrated with the use of an organic interfacial material (e.g. DPC in FIG. 20 or BA in FIG. 21), we can infer that the improved interfacial carrier kinetics is here provided by the Fc moiety. Therefore, without wishing to be bound by theory, it can be concluded that the use of a metallocene interface layer boosts the electron transfer at the perovskite/ETL interface.

### Comparative Solar Cell 6

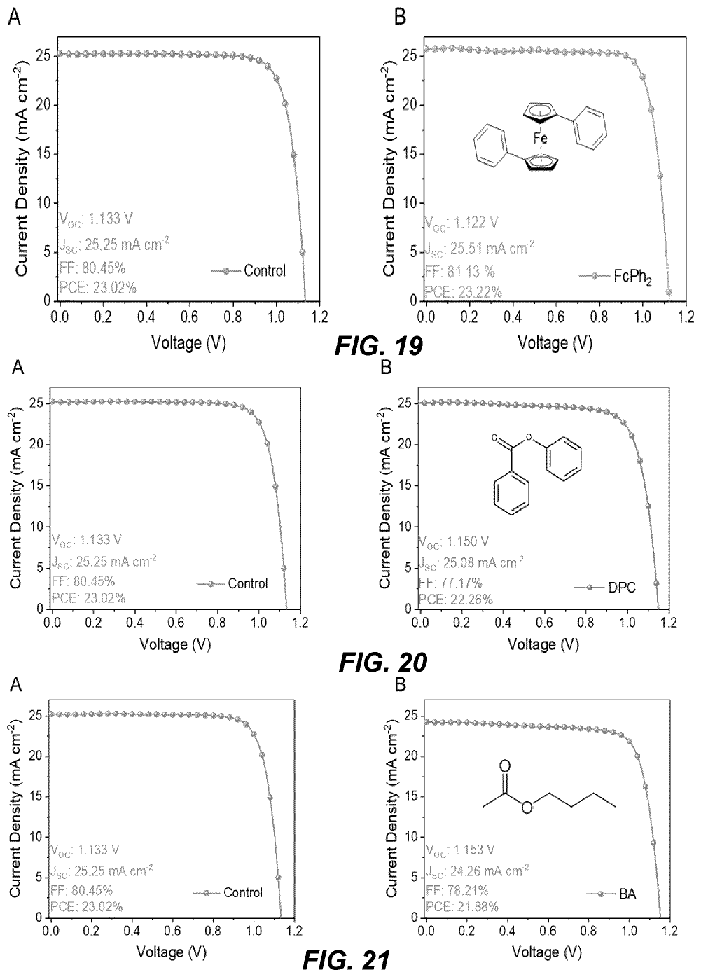

A solar cell was prepared as described for Solar Cell Example 1 except that ferrocene-based material ferrocenylbis-phenyl (FcPh₂) was used as the interface material. The molecular structure of FcPh₂ is inset in FIG. 19B.

It can be seen from FIG. 19B that the short-circuit current, Jsc and fill factor, FF is increased for an interface layer 108 of FcPh₂ as compared to the control device of FIG. 19A with no interlayer. However, the FcPh₂-modified PVSC did not show a significant enhancement in PCE as compared to the control. Without wishing to be bound by any theory, this may be due to the fact that neither phenyl nor ferrocene units can bind or interact with the perovskite, so cannot replace the effect of the carboxylate of FcTc₂ on defect passivation and carrier transport.

### Comparative Solar Cell 7

A solar cell was prepared as described for Solar Cell Example 1 except that Diphenylcarboxylate (DPC) was used as the interface material. The molecular structure of DPC is inset in FIG. 20B.

With reference to FIG. 20B, it can be seen that both the short-circuit current Jsc and FF of DPC-modified PVSC are decreased as compared to the control device of FIG. 20A which does not contain an interface layer. Without wishing to be bound by any theory, this may be due to an electron transport barrier at the perovskite/ETL interface caused by the poor conductivity of the organic DPC interface layer.

### Comparative Solar Cell 8

A solar cell was prepared as described for Solar Cell Example 1 except that Butyl acetate (BA) possessing a high boiling point as the representative ester was used as the interface material. The molecular structure of BA is inset in FIG. 21B.

With reference to FIG. 21B, it can be seen that both the short-circuit current Jsc and FF of BA-modified PVSC are decreased as compared to the control device of FIG. 21A which does not contain an interface layer. Without wishing to be bound by any theory, this may be due to an electron transport barrier at the perovskite/ETL interface caused by the poor conductivity of the organic BA interface layer.

### Density Functional Theory (DFT) Simulations and Electrostatic Potential (ESP) Analysis

Density functional theory (DFT) simulations were performed to study the interaction between a perovskite surface and FcTc₂ molecules. The (001) PbI₂ terminated perovskite surface was chosen as a model, since it has been proven to be stable with the lowest energy configuration. Starting from the ordered interface, enhanced bonding of O from FcTc₂ with Pb from the perovskite surface was observed within a few picoseconds (FIGS. 23A and 23B, see the decrease in bond length L_{Pb—O}). With the interfacial rearrangement, the molecular dynamics reach a stable equilibrium state, in which the bond length of Pb—O is simulated to be 2.65 Å (see FIG. 23C).

Electrostatic potential (ESP) analysis of FcTc₂, shown in FIG. 24, indicates a high electronegativity (−29.79 kcal mol-1) of O in FcTc₂ (the electronegativity of O, S and H atoms is −29.79 kcal mol⁻¹, −8.12 kcal mol⁻¹ and 15.16 kcal mol⁻¹, respectively). This further supports the formation of strong Pb—O bonds between the perovskite surface and FcTc₂.

The XPS analysis discussed with respect to FIG. 4, combined with the DFT simulations of FIG. 23 and the ESP analysis of FIG. 24, indicates that there is a strong interaction between perovskite and FcTc₂, which is beneficial for both passivation of surface defects and stabilization of surface components in perovskite. Thus it can be seen from these DFT simulations of FIG. 23 that the FcTc₂ molecule can bond to uncoordinated Pb defects on the perovskite surface via Pb—O binding or bond formation. This interaction between FcTc₂ and perovskite (and the strong Pb—O binding or bonds) can reduce trap-state densities and suppress non-radiative recombination, which effect is demonstrated by the prolonged carrier lifetime derived from TRPL spectra (Table 1 and FIG. 6) and the reduced defect densities calculated from the SCLC curves (see FIG. 18).

Overall, the realization of high-efficiency perovskite solar cells can be attributed at least in part to the following effects discussed herein:
(i) Interfacial defects passivation. The interface layer 108 (such as FcTc₂) can bond to the uncoordinated Pb defects on perovskite surface via, for example, the Pb—O binding to reduce trap-state densities and suppress non-radiative recombination (see FIGS. 23, 24);
(ii) Electron transport and extract acceleration. The fast electron transfer characteristic of metallocenes (such as ferrocene in FcTc₂) can accelerate electron transport and extraction at the perovskite/ETL interface, which is not possible with insulating organic interface materials (see FIGS. 20 and 21); and
(iii) Improved structural compatibility and molecular flexibility. The application of FcTc₂ and in particular, its thiophene-carboxylate side arms (with potentially donating O and S atoms) to modify the perovskite interface achieves better structural compatibility. Compared with the conventional rigid inorganic materials, FcTc₂ has better molecular flexibility, and can interact more strongly with perovskite and transport layer interfaces.

### Funding Statement

This invention was supported by the ECS grant (21301319) and Natural Science Foundation of Guangdong Province (2019A1515010761), and Imperial College London via the Sir Edward Frankland BP Chair Endowment.

### Appendix 1: Photovoltage Loss (V_{OC}, Loss) Calculation

The detailed V_{OC,loss} can be described by the equation listed below:

$$\begin{matrix}q Δ V = {E}_{g} - {qV}_{OC} \\ = ( {E}_{g} - {qV}_{OC}^{SQ} ) + ( {qV}_{OC}^{SQ} - {qV}_{OC}^{rad} ) + ( {qV}_{OC}^{rad} - {qV}_{OC} ) \\ = ( {E}_{g} - {qV}_{OC}^{SQ} + q Δ {V}_{OC}^{SQ} ) + Δ {qV}_{OC}^{rad} + Δ {qV}_{OC}^{non - r} \\ = q ( Δ {V}_{1} + Δ {V}_{2} + Δ {V}_{3} )\end{matrix} \qquad ( Eq . 1 )$$

where q, ΔV, E_{g} is the elementary charge, the total voltage loss, and the bandgap of perovskite, respectively. V_{OC}^{SQ} is the Shockley-Queisser limit of open circuit voltage, V_{OC}^{rad} is the V_{OC} without non-radiative recombination occurring in PSCs, ΔV_{OC}^{SQ} is the V_{OC} loss due to the non-ideal EQE above bandgap, ΔV_{OC}^{rad} is the V_{OC} loss due to the sub-bandgap radiative recombination, and ΔV_{OC}^{non-rad} is the V_{OC} loss of non-radiative recombination.

As a consequence, the energy loss can be divided into three parts, ΔV₁, ΔV₂ and ΔV₃, which represent: radiative recombination above E_{g}, energy loss from blackbody radiation and voltage loss induced by the nonradiative recombination, respectively.

A photovoltaic bandgap (E_{g,PV}) of 1.548 eV was obtained (for both Comparative Solar Cell 1 and Solar Cell Example 1) from the inflection point of the EQE spectra by locating the maximum point (λ_{g}) of the Gaussian-like derivate ∂EQE/∂λ. E_{g,PV} was defined as the mean peak energy at the absorption edge of the distribution and it should be considered as a convention for the determination of bandgap energy of any solar cells. Since it represents an external property of a photovoltaic device, and not an internal property of a photovoltaic materials, the use of the mean peak energy can enable a more precise estimation of a bandgap of a solar cell device.

According to a previous report, the V_{OC} of a solar cell can be calculated by the equation:

$${V}_{OC} = \frac{{k}_{B} T}{q} ln ( \frac{{J}_{SC}}{{J}_{0}} ) \qquad ( Eq . 2 )$$

where q, k_{B}, T, J_{SC}, Jₒ, represents the element charge, Boltzmann constant, temperature, short-circuit current, and dark saturation current, respectively. The J_{SC} and Jₒ can be described as:

$${J}_{SC} = q {\int }_{0}^{∞} {EQE}_{PV} ( E ) {ϕ}_{AM 1.5} ( E ) dE \qquad ( Eq . 3 )$$

$${J}_{0} = \frac{q}{{EQE}_{EL}} {\int }_{0}^{∞} {EQE}_{PV} ( E ) {ϕ}_{BB} ( E ) dE \qquad ( Eq . 4 )$$

$${ϕ}_{BB} ( E ) = \frac{2 π {E}^{2}}{{h}^{3} {c}^{2}} \frac{1}{exp ( \frac{E}{{k}_{B} T} ) - 1} \qquad ( Eq . 5 )$$

where EQE_{PV}, EQE_{EL} is photovoltaic external quantum efficiency and electroluminescence external quantum efficiency, respectively. ϕ_{AM.5}, ϕ_{BB} is solar cell radiative spectrum and black-body radiative spectrum, respectively. c is light speed in vacuum.

### According to the Schokley-Queisser Limit (S-Q Limit):

(1) The EQE_{PV} is described with Heaviside step function, where

$${EQE}_{PV} ( E ) = \{ \begin{matrix}1 , & E \geq {E}_{g} \\ 0 , & E < {E}_{g}\end{matrix} ;$$

(2) only the photons with energy larger than bandgap (E_{g}) are absorbed;
(3) all recombination is radiative (EQE_{EL}=1).

Therefore, J_{SC} and Jₒ in S-Q limit can be written as:

$${J}_{SC}^{SQ} = q {\int }_{{E}_{g}}^{∞} {ϕ}_{AM 1.5} ( E ) dE \qquad ( Eq . 6 )$$

$${J}_{0}^{SQ} = q {\int }_{{E}_{g}}^{∞} {ϕ}_{BB} ( E ) dE \qquad ( Eq . 7 )$$

Therefore, V_{OC} in S-Q limit is:

$${V}_{OC}^{SQ} = \frac{{k}_{B} T}{q} ln ( \frac{{J}_{SC}^{SQ}}{{J}_{0}^{SQ}} ) \qquad ( Eq . 8 )$$

Considering the theory of S-Q limit, V_{OC}^{SQ} can be degraded to V_{OC} with three components of loss.

The first V_{OC} loss component is due to the non-ideal EQE_{PV}, which is less than 100%. In this situation, short-circuit current is expressed as:

$${J}_{SC} = q {\int }_{0}^{∞} {EQE}_{PV} ( E ) {ϕ}_{AM 1.5} ( E ) dE \qquad ( Eq . 9 )$$

The ΔV_{OC}^{SQ} was calculated as below:

$$Δ {V}_{OC}^{SQ} = {V}_{OC}^{SQ} - \frac{{k}_{B} T}{q} ln ( \frac{{J}_{SC}}{{J}_{0}^{SQ}} ) = \frac{{k}_{B} T}{q} ln ( \frac{{J}_{SC}^{SQ}}{{J}_{SC}} ) \qquad ( Eq . 10 )$$

The second V_{OC} loss component originates from the energy loss related with extra thermal radiation of solar cell in dark. The EQE_{PV} extends into the sub-bandgap region, where the black-body radiation increases with the photo energy lowering. Thus, this sub-bandgap EQE_{PV} increased the dark saturation current. The short-circuit current J_{SC}^{rad} is equal to J_{SC}, and dark saturation current in this condition are written as:

$${J}_{0}^{rad} = q {\int }_{0}^{∞} {EQE}_{PV} ( E ) {ϕ}_{BB} ( E ) dE \qquad ( Eq . 11 )$$

therefore, the radiative V_{OC} loss, ΔV_{OC}^{rad}, is:

$$Δ {V}_{OC}^{rad} = \frac{{k}_{B} T}{q} ln ( \frac{{J}_{SC}}{{J}_{0}^{SQ}} ) - \frac{{k}_{B} T}{q} ln ( \frac{{J}_{SC}}{{J}_{0}^{rad}} ) = \frac{{k}_{B} T}{q} ln ( \frac{{J}_{0}^{rad}}{{J}_{0}^{SQ}} ) \qquad ( Eq . 12 )$$

The third V_{OC} loss component, ΔV_{OC}^{nonrad}, which is attributed to the non-radiative recombination in device, can be calculated as:

$$Δ {V}_{OC}^{nonrad} = \frac{{k}_{B} T}{q} ln ( \frac{{J}_{SC}}{{J}_{0}^{rad}} ) - {V}_{OC} \qquad ( Eq . 13 )$$

According to equations Eq. 4 and Eq. 11, Jₒ^{rad}=EQE_{EL}·J₀, so combining that with Equation Eq. 2, it is seen that Equation Eq. 13 above can be rewritten as:

$$Δ {V}_{OC}^{nonrad} = \frac{{k}_{B} T}{q} ln ( \frac{{J}_{SC}}{{EQE}_{EL} \cdot {J}_{0}} ) - \frac{{k}_{B} T}{q} ln ( \frac{{J}_{SC}}{{J}_{0}} ) = - \frac{{k}_{B} T}{q} ln ( {EQE}_{EL} )$$

Solar Cell Example 1 and Comparative Solar Cell 1 show similar ΔV₁ of ˜274 mV.

As shown in FIG. 44, the PSCs with and without Fc₂ Tc₂ show similar ΔV₁ of ˜274 mV, indicating the radiative recombination is unchanged after surface treatment. As the EQE of the device protrudes into the area below E_{g} and brings about more black-body radiation the highly-sensitive EQE below the bandgap can be characterized to calculate ΔV₂. The calculated ΔV₂ is 20.67 mV and 31.50 mV for Solar Cell Example 1 and Comparative Solar Cell 1, respectively.

ΔV₃ is the V_{OC} loss from the non-radiative recombination, which can be deduced with the equation S22, where EQE_{EL} is the EQE of electroluminescence (EL). The ΔV₃ of Comparative Solar Cell 1 and Solar Cell Example 1 can be calculated to 108.57 and 68.75 mV, respectively. This result further confirms that functional Fc molecules play a role in accelerating interfacial charge transfer and reducing nonradiative recombination.

The external ideality factor (n) can be extracted according to qV_{OC}=E_{g}˜nkT ln(Iₒ/I), where Iₒ is a normalization factor, T is the absolute temperature, I is the incident light intensity, q is the elementary charge, E_{g} is the band gap, k is the Boltzmann constant, and T is the absolute temperature. In general, in FIG. 39, an ideality factor of 1 is associated to bimolecular bond-to-bond radiative recombination of carriers or dominating Shockley-Read-Hall (SRH) trap-assisted recombination with one pinned charge carrier density, while an ideality factor of 2 is associated with dominated SRH recombination without pinning of one charge carrier density.

1. A photovoltaic cell comprising:
a first electrode;
a second electrode;
a perovskite layer and an electron transport layer disposed between the first and second electrodes; and
an interface layer disposed between the perovskite layer and the electron transport layer and in direct contact with the perovskite layer, the interface layer comprising an interfacial compound comprising a metallocene substituted with at least one substituent R¹ comprising at least one of an O, S, N or P atom.

2. The photovoltaic cell according to claim 1 wherein the interfacial compound is a compound of formula (I):
[Metallocene]p (I)
wherein:
Metallocene is a metallocene group comprising a metal bound to two aromatic or heteroaromatic groups Ar¹;
p is at least 1; and
at least one Metallocene is substituted with at least one substituent R¹.

3. The photovoltaic cell according to claim 2 wherein the compound of formula (I) has formula (Ia): 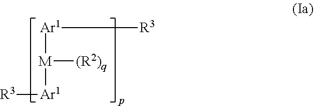
wherein:
M is a metal ion;
Ar¹ in each occurrence is a monocyclic or polycyclic aromatic or heteroaromatic group;
M and the two Ar¹ groups form the Metallocene;
at least one Ar¹ is substituted with at least one R¹;
R² is a group for satisfying the valency of M;
q is 0 or a positive integer; and
R³ in each occurrence is independently H or a substituent.

4. The photovoltaic cell according to claim 1 wherein the metallocene is ferrocene.

5. The photovoltaic cell according to claim 1 wherein R¹ is a group of formula (II):
-A-B (II)
wherein A is a divalent group comprising O, S, N or P; and B is H, C₁₋₁₂ alkyl, optionally substituted aryl or optionally substituted heteroaryl.

6. The photovoltaic cell according to claim 5 wherein A is selected from groups of formulae:
—(R⁵)_{f}—Z—(R⁵)g- (III)
—(R⁶O)ⱼ— (IV)
wherein:
R⁵ in each occurrence is independently a hydrocarbon group;
f and g are each independently 0 or 1;
R⁶ is a C1-4 alkylene group;
j is 1-10; and
Z is O, S, COO, C(═S)O, C(═O)S, CONR⁴, CSNR⁴, OC(═O)O, OC(═O)NR⁴, OC(═O)PR⁴, NR⁴, PR⁴, —OP(═O)(OR⁴)—O—, —NR⁴—P(═O)(NR⁴₂)—NR⁴—, wherein R⁴ is H, optionally substituted C₁₋₁₂ alkyl or optionally substituted phenyl.

7. The photovoltaic cell according to claim 5 wherein A is —O—C(═O)—.

8. The photovoltaic cell according to claim 5 wherein B is selected from optionally substituted phenyl and an optionally substituted 5 membered heteroaryl comprising one or more ring atoms selected from O, S and N.

9. The photovoltaic cell according to claim 5 wherein B is optionally substituted thiophene.

10. The photovoltaic cell according to claim 1 wherein the perovskite layer comprises a perovskite of formula CatPbX₃ or CatSnX₃ wherein Cat is a metal cation, an organic cation or a combination thereof and X is selected from at least one of I, Br and Cl.

11. The photovoltaic cell according to claim 1 wherein the electron transport layer comprises a fullerene.

12. A photovoltaic module comprising a plurality of the photovoltaic cells according to claim 1, the photovoltaic cells connected in series.

13. A compound of formula (I):
[Metallocene]p (I)
wherein:
Metallocene is a metallocene group comprising a metal bound to two aromatic or heteroaromatic groups Ar¹;
p is at least 1; and
at least one Metallocene is substituted with at least one substituent R¹ wherein R¹ is a group of formula (II):
-A-B (II)
wherein A is a divalent group comprising O, S, N or P; and B is optionally substituted aryl or optionally substituted heteroaryl.

14. The compound according to claim 13 wherein Ar¹ is optionally substituted cyclopentadienyl.

15. The compound according to claim 13 wherein Metallocene is ferrocene.

16. The compound according to claim 13 wherein A is selected from groups of formulae:
—(R⁵)_{f}—Z—(R⁵)g- (III)
—(R⁶O)ⱼ— (IV)
wherein:
R⁵ in each occurrence is independently a hydrocarbon group;
f and g are each independently 0 or 1;
R⁶ is a C1-4 alkylene group;
j is 1-10; and
Z is O, S, COO, C(═S)O, C(═O)S, CONR⁴, CSNR⁴, OC(═O)O, OC(═O)NR⁴, OC(═O)PR⁴, NR⁴, PR⁴, —OP(═O)(OR⁴)—O—, —NR⁴—P(═O)(NR⁴₂)—NR⁴—, wherein R⁴ is H, optionally substituted C₁₋₁₂ alkyl or optionally substituted phenyl.

17. The compound according to claim 16 wherein A is —O—C(═O)—.

18. The compound according to claim 13 wherein B is selected from optionally substituted phenyl and an optionally substituted 5 membered heteroaryl comprising one or more ring atoms selected from O, S and N.

19. The compound according to claim 18 wherein B is optionally substituted thiophene.

20. The compound according to claim 16 wherein R⁶ is a C1-4 ethylene group.
